(19) United States
(12) Patent Application Publication
(10) Pub. No.: US 2025/0287755 A1
(43) Pub. Date: Sep. 11, 2025

(54) DISPLAY APPARATUS

(71) Applicant: Samsung Display Co., Ltd., Yongin-si (KR)

(72) Inventors: Jonghwa Park, Yongin-si (KR); Kyungho Kim, Yongin-si (KR)

(21) Appl. No.: 19/069,975

(22) Filed: Mar. 4, 2025

(30) Foreign Application Priority Data
Mar. 5, 2024 (KR) 10-2024-0031528

(51) Int. Cl. H10H 29/49

(52) U.S. Cl. CPC H10H 29/49

(57) ABSTRACT

Provided is a display apparatus including a display area and a non-display area outside the display area, wherein the display apparatus includes a plurality of pixels arranged in the display area, each of the plurality of pixels including a transistor and a light-emitting diode electrically connected to the transistor, a connection line arranged in the display area, the connection line electrically connecting adjacent pixels from among the plurality of pixels to each other, and a peripheral line arranged in the non-display area, wherein a modulus of a conductive layer of the transistor is greater than a modulus of the connection line, and the modulus of the connection line is greater than a modulus of the peripheral line.

### CROSS-REFERENCE TO RELATED APPLICATION

The present application claims priority to and the benefit of Korean Patent Application No. 10-2024-0031528, filed on Mar. 5, 2024, in the Korean Intellectual Property Office, the entire disclosure of which is incorporated by reference herein.

### BACKGROUND

### 1. Field

One or more embodiments of the present disclosure relate to a display apparatus, for example, a flexible display apparatus.

### 2. Description of the Related Art

According to the development of display apparatuses visually displaying electrical signals, various display apparatuses having excellent characteristics, such as reduction in thickness, light weight, and low power consumption, have been introduced. For example, flexible display apparatuses that can be folded and/or rolled into a roll shape have been introduced. Recently, research and development on a stretchable display apparatus that can be changed into various shapes has been actively conducted.

### SUMMARY

One or more embodiments of the present disclosure include a display apparatus capable of concurrently (e.g., simultaneously) securing excellent stretchability while having high mechanical stability. However, these aspects are shown as an example, and the scope of the present disclosure is not limited thereto.

Additional aspects will be set forth in part in the description which follows and, in part, will be apparent from the description, or may be learned by practice of embodiments of the present disclosure.

According to one or more embodiments, a display apparatus includes a display area and a non-display area outside the display area, wherein the display apparatus includes a plurality of pixels arranged in the display area, each of the plurality of pixels including a transistor and a light-emitting diode electrically connected to the transistor, a connection line arranged in the display area, the connection line electrically connecting adjacent pixels from among the plurality of pixels to each other, and a peripheral line arranged in the non-display area, wherein a modulus of a conductive layer of the transistor is greater than a modulus of the connection line, and the modulus of the connection line is greater than a modulus of the peripheral line.

In one or more embodiments, the conductive layer of the transistor, the connection line, and the peripheral line may include different materials.

In one or more embodiments, the modulus of the conductive layer of the transistor may be greater than 100 GPa and less than 1000 GPa.

In one or more embodiments, the conductive layer of the transistor may include a metal thin film.

In one or more embodiments, the modulus of the connection line may be greater than 1 MPa and less than 100 MPa.

In one or more embodiments, the connection line may include a metal nanostructure and an elastic polymer.

In one or more embodiment, the metal nanostructure may include at least one of a silver (Ag) nanoparticle, an Ag nanoflake, or an Ag nanowire.

In one or more embodiments, the elastic polymer may include at least one of polydimethylsiloxane (PDMS), polyurethane (PU), or Ecoflex.

In one or more embodiments, the connection line may further include a carbon-based material, and the carbon-based material includes a carbon nanotube (CNT), a carbon fiber, graphene, graphene oxide, or any combinations thereof.

In one or more embodiments, the modulus of the peripheral line may be greater than 1 kPa and less than 100 kPa.

In one or more embodiments, the peripheral line may include a liquid metal.

In one or more embodiments, the liquid metal may include a eutectic gallium-indium alloy (EGaIn) or a gallium-indium-tin alloy (Galinstan).

In one or more embodiments, each of the conductive layer of the transistor, the connection line, and the peripheral line may include a metal nanostructure and an elastic polymer.

In one or more embodiments, a concentration of the metal nanostructure in the conductive layer of the transistor may be greater than a concentration of the metal nanostructure in the connection line, and the concentration of the metal nanostructure in the connection line may be greater than a concentration of the metal nanostructure in the peripheral line.

In one or more embodiments, the metal nanostructure may include at least one of an Ag nanoparticle, an Ag nanoflake, or an Ag nanowire, and the elastic polymer may include at least one of polydimethylsiloxane (PDMS), polyurethane (PU), or Ecoflex.

In one or more embodiments, the connection line may include a plurality of signal lines and a plurality of voltage lines, and the plurality of signal lines may include at least one of a data line, an emission control line, a scan signal line, an initialization control line, and a bypass control line.

In one or more embodiments, the peripheral line may include at least one of a driving voltage supply line, a common voltage supply line, a fan-out line, a driving circuit input line, or a driving circuit output line.

In one or more embodiments, the display apparatus may further include a gate driving circuit in the non-display area, wherein a modulus of a conductive layer of the gate driving circuit may be less than the modulus of the connection line.

In one or more embodiments, the conductive layer of the gate driving circuit may include a liquid metal.

According to one or more embodiments, a display apparatus includes a display area and a non-display area outside the display area, wherein the display apparatus includes a plurality of pixels arranged in the display area, each of the plurality of pixels including a transistor and a light-emitting diode electrically connected to the transistor, a connection line arranged in the display area, the connection line electrically connecting adjacent pixels from among the plurality of pixels to each other, and a peripheral line arranged in the non-display area, wherein a conductive layer of the transistor includes a metal thin film, the connection line includes a metal nanostructure and an elastic polymer, and the peripheral line includes a liquid metal.

In one or more embodiments, a modulus of the conductive layer of the transistor may be greater than a modulus of the connection line, and the modulus of the connection line may be greater than a modulus of the peripheral line.

In one or more embodiments, the modulus of the conductive layer of the transistor is from about 100 GPa to about 1000 GPa, the modulus of the connection line is from about 1 megapascal (MPa) to about 100 MPa, and the modulus of the peripheral line is from about 1 kilopascal (kPa) to about 100 kPa.

In one or more embodiments, the metal nanostructure may include at least one of an Ag nanoparticle, an Ag nanoflake, or an Ag nanowire, and the elastic polymer may include at least one of polydimethylsiloxane (PDMS), polyurethane (PU), or Ecoflex.

In an embodiment, the liquid metal may include a eutectic gallium-indium alloy (EGaIn) or a gallium-indium-tin alloy (Galinstan).

### BRIEF DESCRIPTION OF THE DRAWINGS

The above and other aspects and features of embodiments of the present disclosure will be more apparent from the following description taken in conjunction with the accompanying drawings, in which:

FIG. 1 is a schematic perspective view of a display apparatus according to one or more embodiments;

FIGS. 2A and 2B are perspective views each illustrating a state in which the display apparatus of FIG. 1 is stretched in a first direction;

FIG. 2C is a perspective view illustrating a state in which the display apparatus of FIG. 1 is stretched in a second direction;

FIG. 2D is a perspective view illustrating a state in which the display apparatus 1 of FIG. 1 is stretched in the first direction and the second direction.

FIG. 2E is a perspective view illustrating a state in which the display apparatus of FIG. 1 is stretched in a third direction;

FIG. 3 is a schematic plan view of a display apparatus according to one or more embodiments;

FIG. 4A is an enlarged plan view of a region A of FIG. 3, which is a portion of the display apparatus according to one or more embodiments;

FIG. 4B is an enlarged plan view of a region A of FIG. 3, which is a portion of the display apparatus according to one or more embodiments;

FIG. 4C is an enlarged plan view of a region A of FIG. 3, which is a portion of the display apparatus according to one or more embodiments;

FIG. 5 is a schematic cross-sectional view of a main island portion and a main bridge portion, which are arranged in a display area of a display apparatus according to one or more embodiments;

FIGS. 6A-6C are equivalent circuit diagrams each illustrating a sub-pixel of a display apparatus according to one or more embodiments;

FIGS. 7A and 7B are schematic cross-sectional views respectively illustrating light-emitting elements of a display apparatus according to one or more embodiments;

FIG. 8A is a schematic configuration diagram of a display apparatus according to one or more embodiments;

FIG. 8B is a schematic diagram illustrating a gate driving circuit of a display apparatus according to one or more embodiments;

FIG. 9A is an enlarged plan view of a main island portion of a display apparatus according to one or more embodiments;

FIG. 9B is a plan view illustrating the arrangement of lines on a main bridge portion of a display apparatus according to one or more embodiments;

FIG. 9C is an enlarged plan view of a peripheral island portion and a peripheral bridge portion of a display apparatus according to one or more embodiments;

FIG. 10 shows the cross-sectional views respectively taken along the line I-I′ of FIG. 9A, the line II-II′ of FIG. 9B, and the line III-III′ of FIG. 9C;

FIG. 11 is a schematic cross-sectional view of a display apparatus according to one or more embodiments;

FIG. 12 is a schematic plan view of a display apparatus according to one or more embodiments; and

FIGS. 13A-13G are schematic perspective views respectively showing embodiments of an electronic device including a display apparatus according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

As the present disclosure allows for various changes and numerous embodiments, particular embodiments will be illustrated in the drawings and described in detail in the written description. Effects, aspects, and features of the present disclosure and methods of achieving the same will be apparent with reference to embodiments and drawings described below in detail. The present disclosure may, however, be embodied in many different forms and should not be construed as being limited to the embodiments set forth herein.

The present disclosure will now be described more fully with reference to the accompanying drawings, in which embodiments of the present disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the present disclosure, and are not intended to preclude the possibility that one or more other features or elements may exist or may be added.

It will be understood that when a layer, region, and/or element is referred to as being formed on another layer, region, and/or element, it can be directly or indirectly formed on the other layer, region, or element. That is, for example, intervening layers, regions, or elements may be present.

Sizes of elements in the drawings may be exaggerated for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the present disclosure, “A and/or B” may include “A,” “B,” or “A and B.” In addition, “at least one of A and B” may include “A,” “B,” or “A and B.”

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

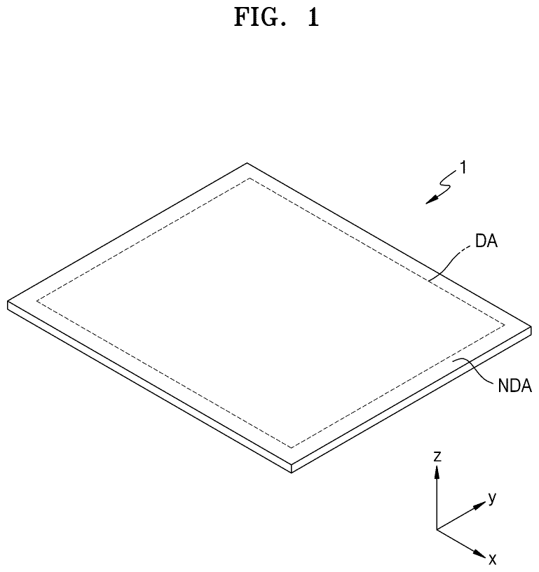

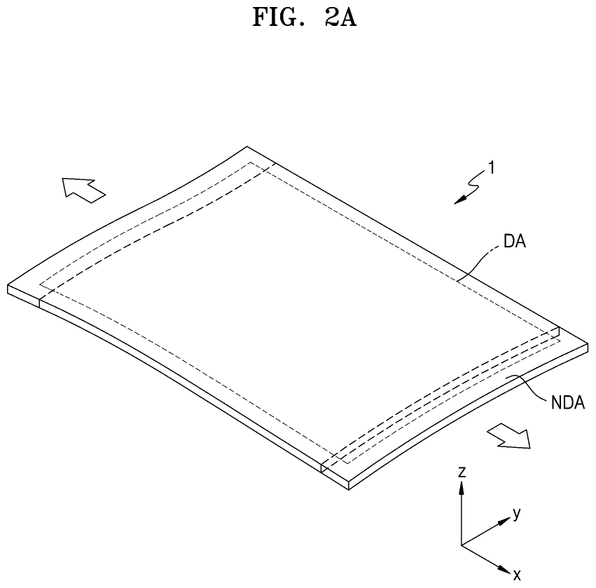

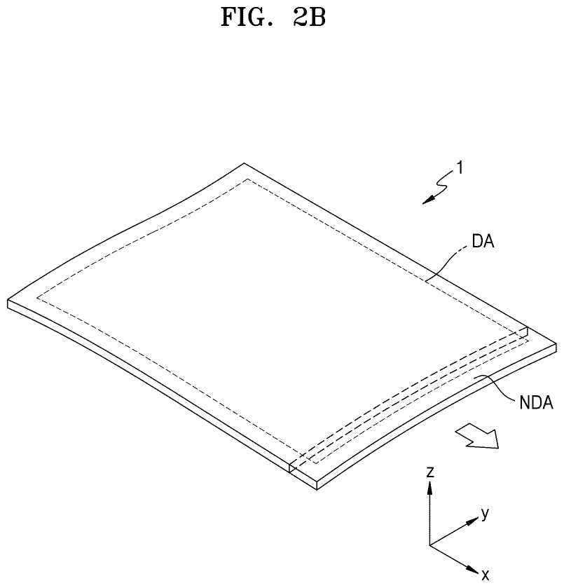

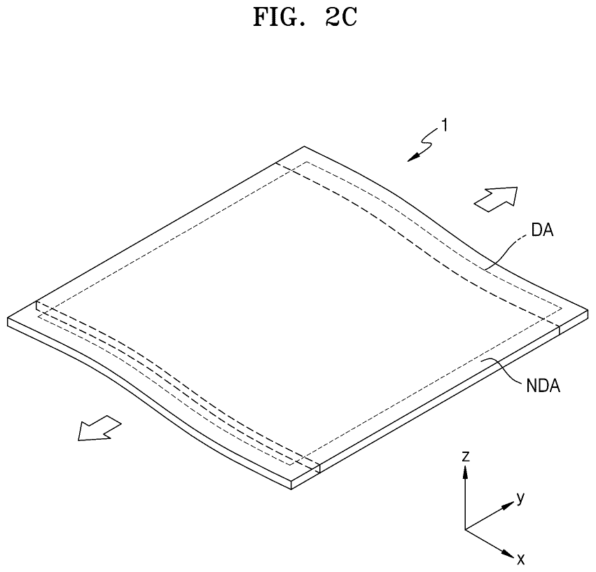

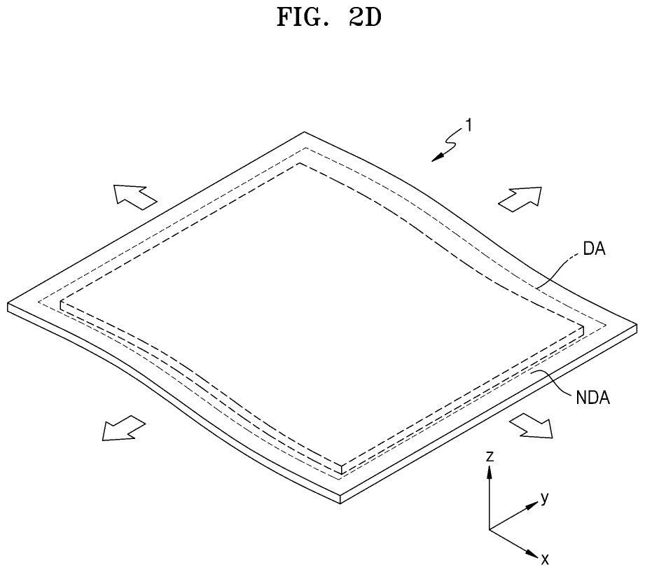

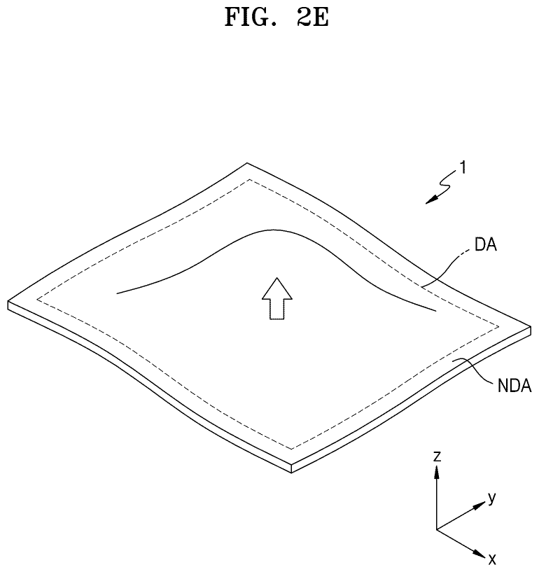

FIG. 1 is a schematic perspective view of a display apparatus 1 according to one or more embodiments. FIGS. 2A and 2B are perspective views each illustrating a state in which the display apparatus 1 of FIG. 1 is stretched in a first direction. FIG. 2C is a perspective view illustrating a state in which the display apparatus 1 of FIG. 1 is stretched in a second direction. FIG. 2D is a perspective view illustrating a state in which the display apparatus 1 of FIG. 1 is stretched in the first direction and the second direction. FIG. 2E is a perspective view illustrating a state in which the display apparatus 1 of FIG. 1 is stretched in a third direction.

Referring to FIG. 1, the display apparatus 1 may include a display area DA and a non-display area NDA around an edge or a periphery of the display area DA. The display area DA may include a plurality of pixels. The display apparatus 1 may provide an image by using light emitted by the plurality of pixels. The non-display area NDA may be arranged outside the display area DA. The non-display area NDA may entirely surround the display area DA.

The display apparatus 1 may be stretched and/or shrunk in various directions. The display apparatus 1 may be stretched in the first direction (e.g., an x direction and/or an −x direction) by an external force applied by an external object or a user. In one or more embodiments, as shown in FIGS. 2A and 2B, the display area DA and/or the non-display area NDA of the display apparatus 1 may be stretched in the first direction (e.g., the x direction and/or the −x direction). For example, as shown in FIG. 2A, the display apparatus 1 may be stretched in the x direction and the −x direction, or the display apparatus 1 may be stretched in the x direction in a state in which one side of the display apparatus 1 is fixed, as shown in FIG. 2B.

The display apparatus 1 may be stretched in the second direction (e.g., a y direction and/or a −y direction) by an external force applied by an external object and/or a user. In one or more embodiments, as shown in FIG. 2C, the display area DA and/or the non-display area NDA of the display apparatus 1 may be stretched in the y direction and the −y direction. In one or more embodiments, the display apparatus 1 may be stretched in the y direction or the −y direction in a state in which one side of the display apparatus 1 is fixed.

The display apparatus 1 may be stretched in a plurality of directions, for example, the first direction (e.g., the x direction and/or the −x direction) and the second direction (e.g., the y direction and/or the −y direction), by an external force applied by an external object or a part of a human's body. As shown in FIG. 2D, the display area DA and/or the non-display area NDA of the display apparatus 1 may be stretched in the +x direction and the ty direction.

The display apparatus 1 may be stretched in a third direction (e.g., a z direction or an −z direction (e.g., a thickness direction of the display apparatus 1)) by an external force applied by an external object or a part of a human's body. In one or more embodiments, FIG. 2E shows that a portion of the display apparatus 1, for example, a partial area of the display area DA, protrudes in the z direction. In one or more embodiments, a portion of the display apparatus 1, for example, a partial area of the display area DA, may protrude in the z direction (or may be depressed in the −z direction).

FIGS. 2A to 2E show that the display apparatus 1 is stretched in the first direction (e.g., the x direction and/or the −x direction), the second direction (e.g., the y direction and/or the −y direction), and/or the third direction (e.g., the z direction and/or the −z direction), but the present disclosure is not limited thereto. In one or more embodiments, the display apparatus 1 may be variously modified into irregular shapes, such as having two or more axes and being bent or twisted.

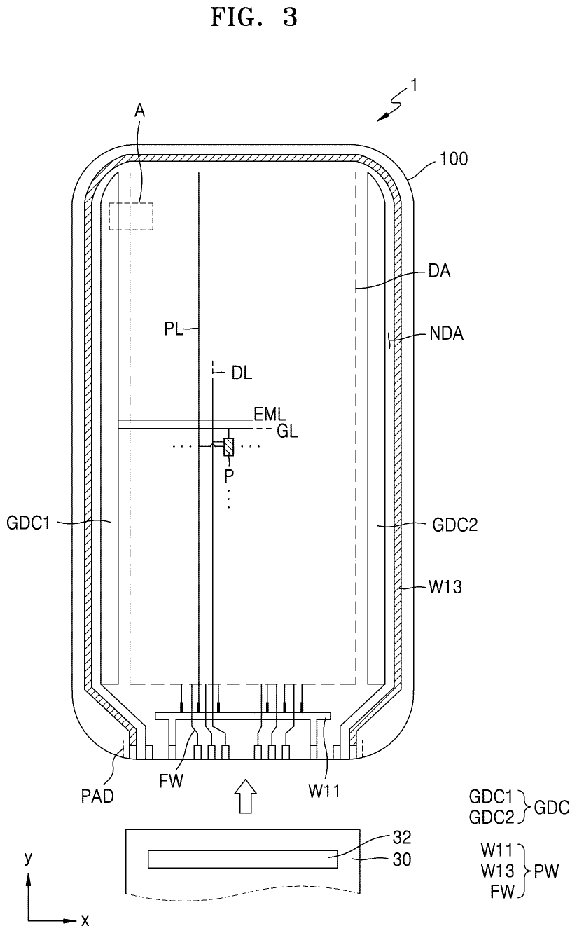

FIG. 3 is a schematic plan view of the display apparatus 1 according to one or more embodiments.

Referring to FIG. 3, various types of components forming the display apparatus 1 are disposed on a substrate 100. The substrate 100 may include the display area DA and the non-display area NDA around (e.g., surrounding) the display area DA along an edge or a periphery of the display area DA. The display area DA may be covered by an encapsulation member to be protected from external air and/or moisture.

Sub-pixels P are arranged in the display area DA of the substrate 100. The sub-pixels P may respectively display images by using light emitted by respective light-emitting elements, such as light-emitting diodes. The respective light-emitting diodes may emit, for example, red, green, and/or blue light.

Each light-emitting diode may be electrically connected to a sub-pixel circuit, and each sub-pixel circuit may include transistors and/or a storage capacitor. Sub-pixel circuits may be respectively electrically connected to peripheral circuits arranged in the non-display area NDA. The peripheral circuits arranged in the non-display area NDA may include a gate driving circuit GDC, a terminal portion PAD, and peripheral lines PW. The peripheral lines PW may include a driving voltage supply line W11, a common voltage supply line W13, and a fan-out line FW.

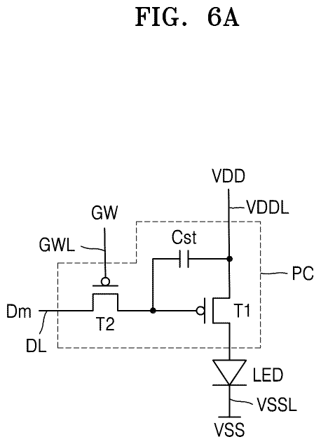

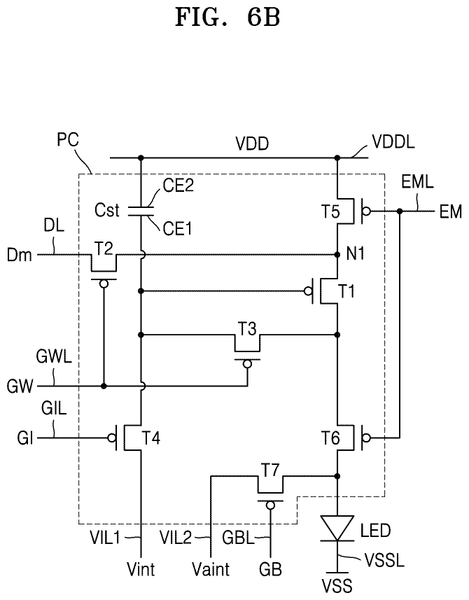

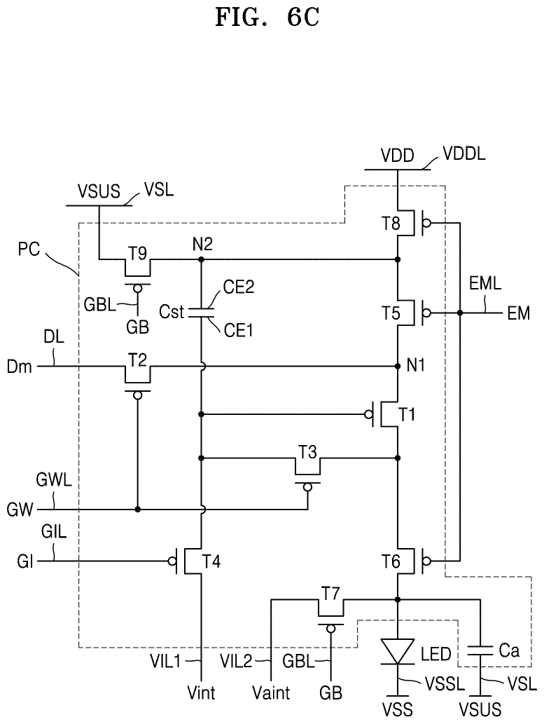

The gate driving circuit GDC may include drivers configured to provide electrical signals to a gate electrode of each of the transistors of the sub-pixel circuits electrically connected to light-emitting elements. In particular, the gate driving circuit GDC may respectively apply scan signals to sub-pixel circuits corresponding to the sub-pixels P through a gate line GL. In addition, the gate driving circuit GDC may apply an emission control signal to each sub-pixel circuit through an emission control line EML. At this time, the gate line GL may include a scan signal line GWL, an initialization control line GIL, and a bypass control line GBL, which will be described below with reference to FIGS. 6B and 6C.

The gate driving circuit GDC may include a first gate driving circuit GDC1 and a second gate driving circuit GDC2, which are arranged on both sides of the display apparatus 1 with the display area DA therebetween. The second gate driving circuit GDC2 may be positioned on the opposite side of the first gate driving circuit GDC1 with the display area DA therebetween and may be substantially parallel with the first gate driving circuit GDC1. Some of the sub-pixel circuits may be electrically connected to the first gate driving circuit GDC1, and the other ones of the sub-pixel circuits may be electrically connected to the second gate driving circuit GDC2. In one or more embodiments, the second gate driving circuit GDC2 may be omitted.

The terminal portion PAD may be arranged on one side of the substrate 100. The terminal portion PAD may be exposed without being covered by an insulating layer to be connected to a display circuit board 30. A display driving unit 32 may be arranged in the display circuit board 30.

The display driving unit 32 may generate a control signal to be transmitted to the first gate driving circuit GDC1 and the second gate driving circuit GDC2. The display driving unit 32 may generate a data signal, and the generated data signal may be transmitted to the sub-pixel circuits of the sub-pixels P via the fan-out line FW and a data line DL connected to the fan-out line FW.

The display driving unit 32 may supply a first power supply voltage VDD (refer to FIGS. 6A-6C) to the driving voltage supply line W11 and supply a second power supply voltage VSS (refer to FIGS. 6A-6C) to the common voltage supply line W13. The first power supply voltage VDD may be applied to the sub-pixel circuit of the sub-pixel P through a driving voltage line PL connected to the driving voltage supply line W11, and the second power supply voltage VSS may be applied to an opposite electrode of a light-emitting element connected to the common voltage supply line W13.

The driving voltage supply line W11 may extend in the x direction from the lower side of the display area DA. The common voltage supply line W13 may have a loop shape with one side open to be partially around (e.g., partially surround) the display area DA.

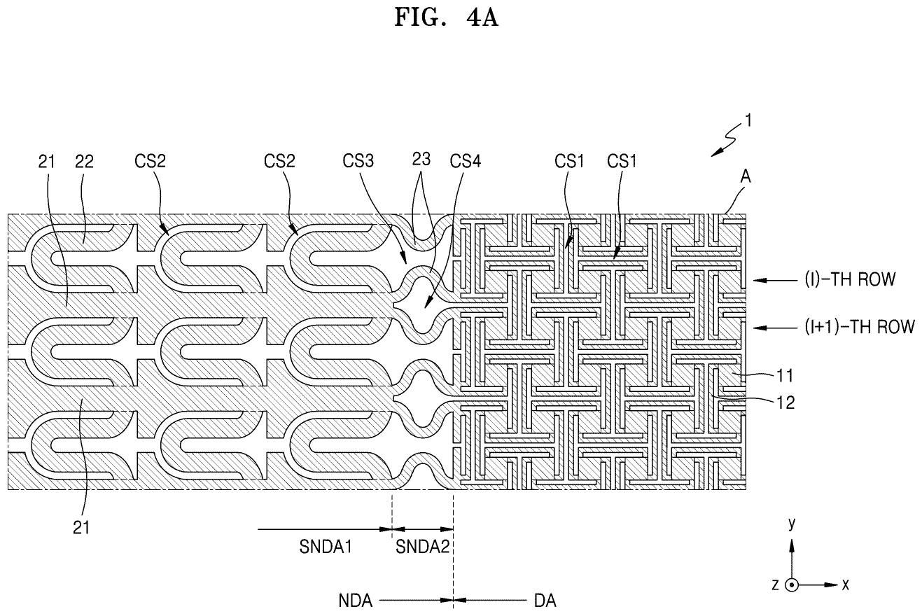

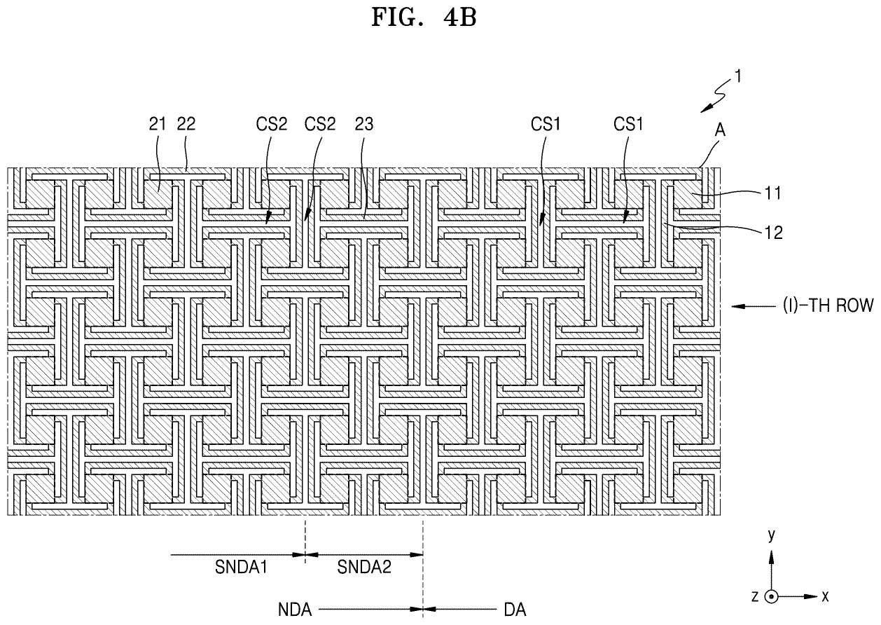

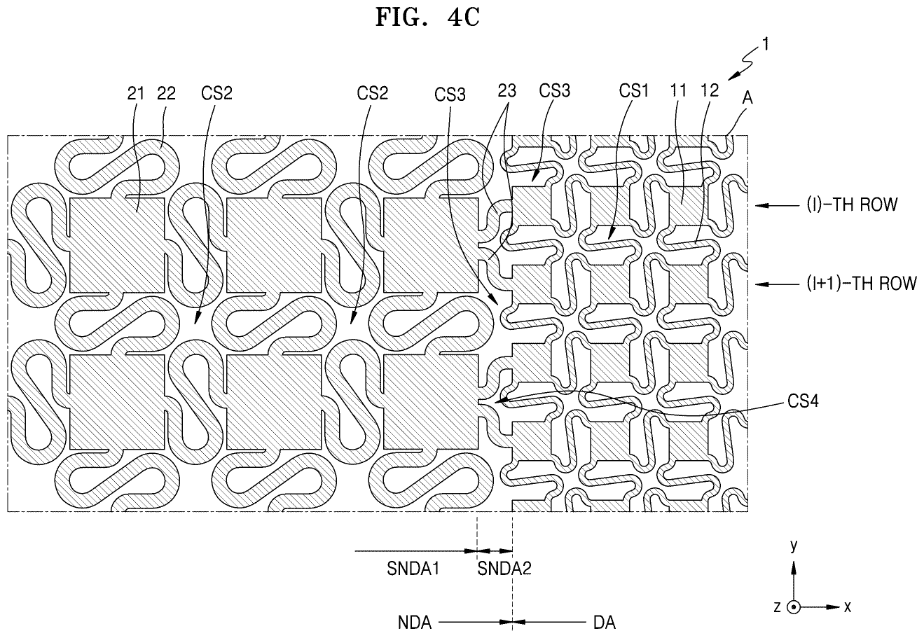

FIG. 4A is an enlarged plan view of a region A of FIG. 3, which is a portion of the display apparatus 1 according to one or more embodiments.

The display apparatus 1 may include, in the display area DA, main island portions 11 spaced (e.g., spaced apart) from each other in the first direction (e.g., the x direction or the −x direction) and the second direction (e.g., the y direction or the −y direction) and main bridge portions 12 connecting adjacent main island portions 11 to each other.

Each main island portion 11 may be connected to a plurality of main bridge portions 12. For example, each main island portion 11 may be connected to four main bridge portions 12. Two main bridge portions 12 may be respectively arranged on both sides of the main island portion 11 in the first direction (e.g., the x direction or the −x direction), and the remaining two main bridge portions 12 may be respectively arranged on both sides of the main island portion 11 in the second direction (e.g., the y direction or the −y direction). In one or more embodiments, the four main bridge portions 12 may be respectively connected to four sides of the main island portion 11. Each of the four main bridge portions 12 may be adjacent to each of corners of the main island portion 11.

The main bridge portions 12 may be spaced (e.g., spaced apart) from each other by a first opening portion CS1 positioned between the main bridge portions 12. In one or more embodiments, the first opening portion CS1 having an approximately H shape and the first opening portion CS1 having an approximately I shape obtained by rotating the above-described H shape by 90 degrees may be alternately and repeatedly arranged along the first direction (e.g., the x direction or the −x direction) and the second direction (e.g., the y direction or the −y direction). Both end portions of each main bridge portion 12 are respectively connected to adjacent main island portions 11, but one side of each main bridge portion 12 may be spaced (e.g., spaced apart) from one side of an adjacent main island portion 11 and/or one side of another main bridge portion 12 by the first opening portion CS1.

The display apparatus 1 may include, in the non-display area NDA, peripheral island portions 21 spaced (e.g., spaced apart) from each other and peripheral bridge portions 22 connecting adjacent peripheral island portions 21 to each other.

Each peripheral island portion 21 may extend in the first direction (e.g., the x direction or the −x direction). The peripheral island portions 21 may be spaced (e.g., spaced apart) from each other in the second direction (e.g., the y direction or the −y direction) crossing the first direction (e.g., the x direction or the −x direction). Each peripheral island portion 21 may include the drivers of the gate driving circuit GDC described above with reference to FIG. 3.

The peripheral bridge portion 22 may have a serpentine shape. The length of the peripheral bridge portion 22 may be greater than the shortest distance between adjacent peripheral island portions 21 in the second direction (e.g., the y direction or the −y direction). In one or more embodiments, the peripheral bridge portion 22 may have an approximate omega (Ω) shape that is convex toward the first direction (e.g., the x direction or the −x direction). The peripheral bridge portions 22 may be arranged between adjacent peripheral island portions 21 and may be spaced (e.g., spaced apart) from each other.

The peripheral bridge portions 22 between adjacent peripheral island portions 21 may be spaced (e.g., spaced apart) from each other by a second opening portion CS2. The second opening portions CS2 and the peripheral bridge portions 22 may be alternately arranged along the first direction (e.g., the x direction or the −x direction) between adjacent peripheral island portions 21. The second opening portions CS2 may have the same shape. Both end portions of each peripheral bridge portion 22 are respectively connected to adjacent peripheral island portions 21, but one side of each peripheral bridge portion 22 may be spaced (e.g., spaced apart) from one side of the adjacent peripheral island portion 21 and/or one side of another peripheral bridge portion 22 by the second opening portion CS2.

Any one peripheral island portion 21 arranged in the non-display area NDA may correspond to the main island portions 11 of a plurality of rows arranged in the display area DA. For example, any one peripheral island portion 21 arranged in the non-display area NDA may correspond to the main island portions 11 arranged in an (I)-th row and the main island portions 11 arranged in an (I+1)-th row in the display area DA (where I is a positive number greater than 0). FIG. 4A shows that one peripheral island portion 21 corresponds to two rows of the main island portions 11, but the present disclosure is not limited thereto. In one or more embodiments, any one peripheral island portion 21 arranged in the non-display area NDA may correspond to n rows of the main island portions 11 arranged in the display area DA (where n is a positive number of 3 or more).

The non-display area NDA may include a first sub-non-display area SNDA1 in which the peripheral island portions 21 and the peripheral bridge portions 22 described above are arranged and a second sub-non-display area SNDA2 between the first sub-non-display area SNDA1 and the display area DA. Sub-bridge portions 23 connecting the display area DA to the first sub-non-display area SNDA1 may be arranged in the second sub-non-display area SNDA2. One end portion of a sub-bridge portion 23 may be connected to the peripheral island portion 21 and/or the peripheral bridge portion 22, and the other end portion of the sub-bridge portion 23 may be connected to the main island portion 11 and/or the main bridge portion 12.

The sub-bridge portion 23 may have a serpentine shape. In one or more embodiments, the shape of the sub-bridge portion 23 may be different from the shape of each of the main bridge portion 12 and the peripheral bridge portion 22. In one or more embodiments, as shown in FIG. 4A, the sub-bridge portion 23 may have an approximate omega (Ω) shape that is convex toward the second direction (e.g., the y direction or the −y direction). Adjacent sub-bridge portions 23 arranged in the second direction (e.g., the y direction or the −y direction) may have structures that are symmetrical to each other, for example, one of the adjacent sub-bridge portions 23 arranged along the second direction (e.g., the y direction or the −y direction) may be convex in the y direction, and the other one of the adjacent sub-bridge portions 23 may be convex in the −y direction. A structure in which third opening portions CS3 and fourth opening portions CS4, which have different shapes, are repeated may be provided between the sub-bridge portions 23. The width of the sub-bridge portion 23 may be different from the width of the main bridge portion 12 and the width of the peripheral bridge portion 22. In one or more embodiments, the width of the sub-bridge portion 23 may be greater than the width of the main bridge portion 12 and may be less than the width of the peripheral bridge portion 22.

FIG. 4A shows that the peripheral island portion 21 and the peripheral bridge portion 22 of the non-display area NDA have different shapes from the main island portion 11 and the main bridge portion 12 of the display area DA, respectively. In one or more embodiments, the peripheral island portion 21 and the peripheral bridge portion 22 of the non-display area NDA may have the same shapes as the main island portion 11 and the main bridge portion 12 of the display area DA, respectively.

FIG. 4B is an enlarged plan view of the region A of FIG. 3, which is a portion of the display apparatus 1 according to one or more embodiments.

Referring to FIG. 4B, the display apparatus 1 may include the main island portions 11 spaced (e.g., spaced apart) from each other in the display area DA and the main bridge portions 12 spaced (e.g., spaced apart) from each other by the first opening portion CS1 and connecting adjacent main island portions 11 to each other. The structure of the display area DA of FIG. 4B may be the same as the structure of the display area DA described above with reference to FIG. 4A.

The display apparatus 1 may include the peripheral island portions 21 and the peripheral bridge portions 22, which are arranged in the non-display area NDA. In one or more embodiments, the peripheral island portions 21 and the peripheral bridge portions 22 may have substantially the same shapes as the main island portions 11 and the main bridge portions 12, respectively.

The peripheral island portions 21 may be spaced (e.g., spaced apart) from each other in the first direction (e.g., the x direction or the −x direction) and the second direction (e.g., the y direction or the −y direction) in a non-display area, for example, the non-display area NDA. The peripheral bridge portions 22 may be respectively connected to adjacent peripheral island portions 21. The peripheral bridge portions 22 may be spaced (e.g., spaced apart) from each other by the second opening portion CS2 positioned between the peripheral bridge portions 22.

The second opening portion CS2 may have substantially the same shape as the first opening portion CS1. For example, the second opening portion CS2 having an approximately H shape and the second opening portion CS2 having an approximately I shape may be alternately and repeatedly arranged in a non-display area, for example, the non-display area NDA. Both end portions of each peripheral bridge portion 22 are respectively connected to adjacent peripheral island portions 21, but one side of each peripheral bridge portion 22 may be spaced (e.g., spaced apart) from one side of the adjacent peripheral island portion 21 and/or one side of another peripheral bridge portion 22 by the second opening portion CS2.

Each peripheral island portion 21 may be connected to four peripheral bridge portions 22. Each peripheral island portion 21 may include the drivers of the gate driving circuit GDC described above with reference to FIG. 3.

The peripheral island portions 21 of any one row arranged in the non-display area NDA may correspond to the main island portions 11 of any one row arranged in the display area DA. For example, the peripheral island portions 21 arranged in an (I)-th row along the first direction (e.g., the x direction or the −x direction) in the non-display area NDA may correspond to the main island portions 11 arranged in the same row in the display area DA, for example, the (I)-th row (where I is a positive number greater than 0).

The display apparatus 1 may include the sub-bridge portions 23 arranged in the second sub-non-display area SNDA2 connecting the display area DA to the first sub-non-display area SNDA1. The non-display area NDA may include the first sub-non-display area SNDA1 in which the peripheral island portions 21 and the peripheral bridge portions 22 are arranged, and the second sub-non-display area SNDA2 including the sub-bridge portions 23 and positioned between the first sub-non-display area SNDA1 and the display area DA. The sub-bridge portion 23 may be substantially the same as the main bridge portion 12 and the peripheral bridge portion 22. For example, the width of the sub-bridge portion 23 may be equal to the width of the main bridge portion 12 and the width of the peripheral bridge portion 22.

FIG. 4C is an enlarged plan view of the region A of FIG. 3, which is a portion of the display apparatus 1 according to one or more embodiments.

Referring to FIG. 4C, the display apparatus 1 may include, in the display area DA, the main island portions 11 spaced (e.g., spaced apart) from each other in the first direction (e.g., the x direction or the −x direction) and the second direction (e.g., the y direction or the −y direction), and the main bridge portions 12 connecting adjacent main island portions 11 to each other.

The main bridge portions 12 may be arranged to be spaced (e.g., spaced apart) from each other by the first opening portion CS1 positioned between the main bridge portions 12. The main bridge portion 12 may have a serpentine shape. For example, as shown in FIG. 4C, the main bridge portion 12 may have an approximate shape of ‘the letter S’.

Each main island portion 11 may be connected to a plurality of main bridge portions 12. For example, each main island portion 11 may be connected to four main bridge portions 12. Two main bridge portions 12 may be respectively arranged on both sides of the main island portion 11 in the first direction (e.g., the x direction or the −x direction), and the remaining two main bridge portions 12 may be respectively arranged on both sides of the main island portion 11 in the second direction (e.g., the y direction or the −y direction). The four main bridge portions 12 may be respectively connected to four sides of the main island portion 11. Each of the four main bridge portions 12 may be adjacent to each of the corners of the main island portion 11.

The display apparatus 1 may include, in a non-display area, for example, the non-display area NDA shown in FIG. 4C, the peripheral island portions 21 spaced (e.g., spaced apart) from each other in the first direction (e.g., the x direction or the −x direction) and the second direction (e.g., the y direction or the −y direction), and the peripheral bridge portions 22 connecting adjacent peripheral island portions 21 to each other.

The peripheral bridge portions 22 may be arranged to be spaced (e.g., spaced apart) from each other by the second opening portion CS2 positioned between the peripheral bridge portions 22. The peripheral bridge portion 22 may have a serpentine shape. For example, as shown in FIG. 4C, the peripheral bridge portion 22 may have an approximate shape of ‘the letter S’. The size and/or width of the peripheral bridge portion 22 may be different from the size and/or width of the main bridge portion 12. For example, the size and/or the width of the peripheral bridge portion 22 may be greater than the size and/or width of the main bridge portion 12. The radius of curvature of a rounded portion of the peripheral bridge portion 22 may be different from the radius of curvature of a rounded portion of the main bridge portion 12. For example, the radius of curvature of the rounded portion of the peripheral bridge portion 22 may be greater than the radius of curvature of the rounded portion of the main bridge portion 12.

Each peripheral island portion 21 may be connected to a plurality of peripheral bridge portions 22. Each peripheral island portion 21 may be connected to four peripheral bridge portions 22. Two peripheral bridge portions 22 may be respectively arranged on both sides of the peripheral island portion 21 in the first direction (e.g., the x direction or the −x direction), and the remaining two peripheral bridge portions 22 may be respectively arranged on both sides of the peripheral island portion 21 in the second direction (e.g., the y direction or the −y direction). In one or more embodiments, four peripheral bridge portions 22 may be respectively connected to four sides of the peripheral island portion 21. Each peripheral bridge portion 22 may be connected to the central portion of each side of the peripheral island portion 21.

The peripheral island portions 21 of any one row arranged in the non-display area NDA may correspond to the main island portions 11 of a plurality of rows arranged in the display area DA. For example, the peripheral island portions 21 of any one row arranged in the non-display area NDA may correspond to the main island portions 11 arranged in the (I)-th row and the main island portions 11 arranged in the (I+1)-th row of the display area DA. In one or more embodiments, the peripheral island portions 21 of any one row may correspond to n rows of the main island portions 11 (where n is a positive number of 3 or more).

The non-display area NDA may include a first sub-non-display area SNDA1 in which the peripheral island portions 21 and the peripheral bridge portions 22 described above are arranged and a second sub-non-display area SNDA2 between the first sub-non-display area SNDA1 and the display area DA. The sub-bridge portions 23 connecting the display area DA to the first sub-non-display area SNDA1 may be arranged in the second sub-non-display area SNDA2. One end portion of the sub-bridge portion 23 may be connected to the peripheral island portion 21, and the other end portion of the sub-bridge portion 23 may be connected to the main island portion 11. For example, one end portion of the sub-bridge portion 23 may be connected to the central portion of one side of the peripheral island portion 21, and the other end portion of the sub-bridge portion 23 may be connected to the central portion of one end of the main island portion 11.

The sub-bridge portion 23 may have a serpentine shape. In one or more embodiments, the shape of the sub-bridge portion 23 may be different from the shape of each of the main bridge portion 12 and the peripheral bridge portion 22. The width of the sub-bridge portion 23 may be different from the width of the main bridge portion 12 and the width of the peripheral bridge portion 22. The width of the sub-bridge portion 23 may be greater than the width of the main bridge portion 12 and may be less than the width of the peripheral bridge portion 22. The third opening portion CS3 and the fourth opening portion CS4, which have different shapes, may be alternately arranged between the sub-bridge portions 23 along the second direction (e.g., the y direction or the −y direction).

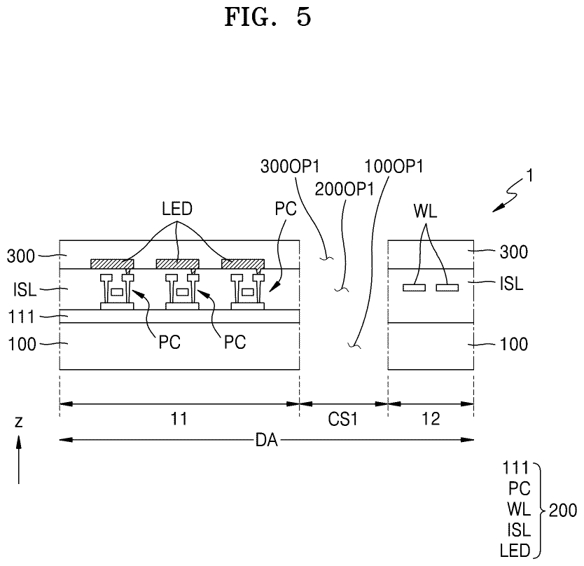

FIG. 5 is a schematic cross-sectional view of a main island portion and a main bridge portion, which are arranged in a display area of a display apparatus according to one or more embodiments.

Referring to FIG. 5, the main island portion 11 and the main bridge portion 12, which are arranged in the display area DA, may be spaced (e.g., spaced apart) from each other with the first opening portion CS1 therebetween. The main island portion 11 may include light-emitting elements LED and corresponding circuits electrically connected to the light-emitting elements LED and configured to drive the light-emitting elements LED, for example, a pixel driving circuit unit PC, and the main bridge portion 12 may include a connection line WL electrically connected to the pixel driving circuit units PC respectively arranged in adjacent main island portions 11.

When looking at the main island portion 11, a buffer layer 111 including an inorganic insulating material may be disposed on the substrate 100, and the pixel driving circuit unit PC may be disposed on the buffer layer 111. An insulating layer ISL including an inorganic insulating material and/or an organic insulating material may be arranged between the pixel driving circuit unit PC and the light-emitting element LED. The light-emitting element LED may be disposed on the insulating layer ISL and may be electrically connected to a corresponding pixel driving circuit unit PC. The light-emitting elements LED may emit light of different colors or the same color. In one or more embodiments, the light-emitting elements LED may respectively emit red, green, and/or blue light. In one or more embodiments, the light-emitting elements LED may emit white light. In one or more other embodiments, the light-emitting elements LED may respectively emit red, green, blue, and white light.

The substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, and/or cellulose acetate propionate. In one or more embodiments, the substrate 100 may be a single layer including the polymer resin described above. In one or more other embodiments, the substrate 100 may have a multi-layered structure including a base layer including the polymer resin described above, and a barrier layer including an inorganic insulating material. The substrate 100 including the polymer resin may be flexible, rollable, and/or bendable.

In one or more embodiments, FIG. 5 shows three pixel driving circuit units PC arranged in each main island portion 11, and three light-emitting elements LED connected to each of the pixel driving circuit units PC, but the present disclosure is not limited thereto. In one or more other embodiments, the number of each of the pixel driving circuit units PC and the light-emitting elements LED, which are arranged in the main island portion 11, may be one, two, or four or more.

An encapsulation layer 300 may be disposed on the light-emitting element LED and may protect the light-emitting element LED from external force and/or moisture penetration. The encapsulation layer 300 may include an inorganic encapsulation layer and/or an organic encapsulation layer. In one or more embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In one or more other embodiments, the encapsulation layer 300 may include an organic material such as resin. In some embodiments, the encapsulation layer 300 may include urethane epoxy acrylate. The encapsulation layer 300 may include a photosensitive material, for example, a material such as photoresist.

When looking at the main bridge portion 12, the insulating layer ISL including an organic insulating material may be disposed on the substrate 100. When the display apparatus 1 is stretched, the main bridge portion 12, which is relatively transformed, may not include a layer including an inorganic insulating material that is prone to cracks, unlike the main island portion 11.

In one or more embodiments, the substrate 100 corresponding to the main bridge portion 12 may have the same stacked structure as the substrate 100 corresponding to the main island portion 11. In one or more embodiments, the substrate 100 corresponding to the main bridge portion 12 and the substrate 100 corresponding to the main island portion 11 may be polymer resin layers formed together in the same process. In one or more other embodiments, the substrate 100 corresponding to the main bridge portion 12 may have a stacked structure that is different from the substrate 100 corresponding to the main island portion 11. In one or more embodiments, the substrate 100 corresponding to the main island portion 11 may have a multi-layered structure including a base layer including a polymer resin and a barrier layer including an inorganic insulating material, and the substrate 100 corresponding to the main bridge portion 12 may have a structure of a polymer resin layer without a layer including an inorganic insulating material.

As described above, the connection lines WL of the main bridge portion 12 may be signal lines (e.g., gate lines, data lines, and/or the like) for providing electrical signals to transistors included in the pixel driving circuit unit PC of the main island portion 11, or may be voltage lines (e.g., driving voltage lines, initialization voltage lines, and/or the like) for providing voltages. The encapsulation layer 300 may also be arranged in the main bridge portion 12. In one or more other embodiments, the encapsulation layer 300 may not be present in the main bridge portion 12.

Referring to FIGS. 4A-4C, and 5, the substrate 100 corresponding to the main island portion 11 and the substrate 100 corresponding to the main bridge portion 12 may be connected to each other. In other words, the plan views previously shown in FIGS. 4A-4C may be substantially the same as the plan view of the substrate 100 of FIG. 5. In other words, the substrate 100 may include an area corresponding to the main island portion 11, an area corresponding to the main bridge portion 12, and an opening 100OP1 having the same shape as the first opening portion CS1.

Similarly, the encapsulation layer 300 corresponding to the main island portion 11 and the encapsulation layer 300 corresponding to the main bridge portion 12 may be connected to each other. For example, the plan views previously shown in FIGS. 4A-4C may be substantially the same as the plan view of the encapsulation layer 300. In other words, the encapsulation layer 300 may include an area corresponding to the main island portion 11, an area corresponding to the main bridge portion 12, and an opening 300OP1 having the same shape as the first opening portion CS1.

A circuit-light-emitting element layer 200 between the substrate 100 and the encapsulation layer 300 may include the buffer layer 111, the pixel driving circuit unit PC, the connection line WL, the insulating layer ISL, and the light-emitting element LED. Similar to the substrate 100, the plan views previously shown in FIGS. 4A-4C may be substantially the same as the plan view of the circuit-light-emitting element layer 200. In other words, the circuit-light-emitting element layer 200 may include an opening 200OP1 having the same shape as the first opening portion CS1.

FIGS. 6A-6C are equivalent circuit diagrams each illustrating a sub-pixel of the display apparatus 1 according to one or more embodiments.

Referring to FIG. 6A, the light-emitting element LED corresponding to the sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to signal lines and voltage lines. The signal lines may include a gate line GL (refer to FIG. 3) such as a scan signal line GWL, and a data line DL, and the voltage lines may include a first voltage line VDDL. At this time, the first voltage line VDDL may be connected to a driving voltage supply line W11 (refer to FIG. 3), and a second voltage line VSSL may be connected to a common voltage supply line W13 (refer to FIG. 3).

The second transistor T2 may be a switching transistor and may be electrically connected to the scan signal line GWL and the data line DL. The scan signal line GWL may provide a scan signal GW to a gate electrode of the second transistor T2. The second transistor T2 may be configured to transmit, to the first transistor T1, a data signal Dm input from the data line DL according to the scan signal GW input from the scan signal line GWL.

The storage capacitor Cst may be electrically connected to the second transistor T2 and the first voltage line VDDL, and may store a voltage corresponding to the difference between a voltage received from the second transistor T2 and the first power supply voltage VDD supplied by the first voltage line VDDL.

The first transistor T1 is a driving transistor, which may control a driving current flowing through the light-emitting element LED. One electrode of the first transistor T1 may be connected to the first voltage line VDDL and the storage capacitor Cst and the other electrode of the first transistor T1 may be connected to the light-emitting element LED. The first transistor T1 may control the driving current flowing through the light-emitting element LED from the first voltage line VDDL in accordance with a voltage value stored in the storage capacitor Cst. The light-emitting element LED may emit light having a certain brightness according to the driving current. A first electrode of the light-emitting element LED may be electrically connected to the first transistor T1, and a second electrode thereof may be electrically connected to the second voltage line VSSL providing the second power supply voltage VSS.

Although FIG. 6A illustrates that the pixel driving circuit unit PC includes two transistors and one storage capacitor, in one or more embodiments, the pixel driving circuit unit PC may include three or more transistors.

Referring to FIG. 6B, the pixel driving circuit unit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit unit PC is electrically connected to signal lines and voltage lines. The signal lines may include the scan signal line GWL, the bypass control line GBL, an initialization control line GIL, a gate line GL (refer to FIG. 3) such as the emission control line EML, and the data line DL. The voltage lines may include first and second initialization voltage lines VIL1 and VIL2, the first voltage line VDDL, and the second voltage line VSSL. At this time, the first voltage line VDDL may be connected to a driving voltage supply line W11 (refer to FIG. 3), and the second voltage line VSSL may be connected to a common voltage supply line W13 (refer to FIG. 3).

The first voltage line VDDL may transmit the first power supply voltage VDD to the first transistor T1. The first initialization voltage line VIL1 may transmit a first initialization voltage Vint initializing the first transistor T1 to the pixel driving circuit unit PC. The second initialization voltage line VIL2 may transmit a second initialization voltage Vaint initializing a first electrode of the light-emitting element LED to the pixel driving circuit unit PC.

The first transistor T1 may be electrically connected to the first voltage line VDDL via the fifth transistor T5 and may be electrically connected to the light-emitting element LED via the sixth transistor T6. The first transistor T1 serves as a driving transistor and receives the data signal Dm according to a switching operation of the second transistor T2 to supply a driving current to the light-emitting element LED.

The second transistor T2 is a data write transistor, which is electrically connected to the scan signal line GWL and the data line DL. The second transistor T2 may be connected between the data line DL and a first node N1 connected to the one electrode of the first transistor T1. The second transistor T2 is electrically connected to the first voltage line VDDL via the fifth transistor T5. The second transistor T2 is turned on according to the scan signal GW received through the scan signal line GWL and performs a switching operation of providing the data signal Dm provided with the data line DL to the first node N1.

The third transistor T3 is electrically connected to the scan signal line GWL and is electrically connected to the light-emitting element LED via the sixth transistor T6. The third transistor T3 may be connected between a gate electrode and the other electrode of the first transistor T1. The third transistor T3 may be turned on according to the scan signal GW received through the scan signal line GWL to diode-connect the first transistor T1.

The fourth transistor T4 is a first initialization transistor, which is electrically connected to the initialization control line GIL and the first initialization voltage line VIL1. The fourth transistor T4 may be connected between the gate electrode of the first transistor T1 and the first initialization voltage line VIL1. The fourth transistor T4 is turned on according to an initialization control signal GI received through the initialization control line GIL to transmit the first initialization voltage Vint from the first initialization voltage line VIL1 to the gate electrode of the first transistor T1 to initialize a voltage of the gate electrode of the first transistor T1. The initialization control signal GI may correspond to a scan signal from another pixel driving circuit unit arranged in a previous row of the corresponding pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML at their respective gate electrodes and are concurrently (e.g., simultaneously) turned on according to an emission control signal EM received through the emission control line EML to form a current path so that a driving current may flow in a direction from the first voltage line VDDL to the light-emitting element LED.

The seventh transistor T7 is a second initialization transistor, which may be electrically connected to the bypass control line GBL, the second initialization voltage line VIL2, and the sixth transistor T6 or the first electrode of the light-emitting element LED. The seventh transistor T7 may be turned on according to a bypass control signal GB received through the bypass control line GBL and may transmit the second initialization voltage Vaint from the second initialization voltage line VIL2 to the first electrode of the light-emitting element LED to initialize the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to the difference between voltages of both ends of the first voltage line VDDL and the gate electrode of the first transistor T1.

Referring to FIG. 6C, the pixel driving circuit unit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit unit PC is electrically connected to signal lines and voltage lines. The signal lines may include the scan signal line GWL, the bypass control line GBL, the initialization control line GIL, a gate line such as the emission control line EML, and the data line DL. The voltage lines may include the first and second initialization voltage lines VIL1 and VIL2, a maintenance voltage line VSL, the first voltage line VDDL, and a second voltage line VSSL. At this time, the first voltage line VDDL may be connected to the driving voltage supply line W11 (refer to FIG. 3), and the second voltage line VSSL may be connected to the common voltage supply line W13 (refer to FIG. 3).

The first voltage line VDDL may transmit the first power supply voltage VDD to the first transistor T1. The first initialization voltage line VIL1 may transmit a first initialization voltage Vint initializing the first transistor T1 to the pixel driving circuit unit PC. The second initialization voltage line VIL2 may transmit a second initialization voltage Vaint initializing a first electrode of the light-emitting element LED to the pixel driving circuit unit PC. The maintenance voltage line VSL may provide a maintenance voltage VSUS to a second node N2 (for example, the second electrode CE2 of the storage capacitor Cst) and to the auxiliary capacitor Ca, during an initialization section and a data write section.

The first transistor T1 may be connected between a first node N1 and the sixth transistor T6. The first transistor T1 may be electrically connected to the first voltage line VDDL via the fifth transistor T5 and the eighth transistor T8, and may be electrically connected to the light-emitting element LED via the sixth transistor T6. The first transistor T1 may function as a driving transistor and receive the data signal Dm via the first node N1 according to the switching operation of the second transistor T2 to supply the driving current to the light-emitting element LED.

The second transistor may be connected between the data line DL and the first node N1. The second transistor T2 is electrically connected to the scan signal line GWL and the data line DL and is electrically connected to the first voltage line VDDL via the fifth transistor T5 and the eighth transistor T8. The second transistor T2 is turned on in response to the scan signal GW received through the scan signal line GWL and performs a switching operation of transmitting the data signal Dm transmitted through the data line DL to the first node N1.

The third transistor T3 may be connected between a gate electrode and the other electrode of the first transistor T1 that is connected to the sixth transistor T6. The third transistor T3 is electrically connected to the scan signal line GWL and is electrically connected to the light-emitting element LED via the sixth transistor T6. The third transistor T3 may be turned on in response to the scan signal GW received through the scan signal line GWL to diode-connect the first transistor T1, thereby compensating for a threshold voltage of the first transistor T1.

The fourth transistor T4 may be connected between the gate electrode of the first transistor T1 and the first initialization voltage line VIL1. The fourth transistor T4 is electrically connected to the initialization control line GIL and the first initialization voltage line VIL1 and turned on in response to the initialization control signal GI received through the initialization control line GIL to transmit the first initialization voltage Vint from the first initialization voltage line VIL1 to the gate electrode of the first transistor T1 to initialize the voltage of the gate electrode of the first transistor T1. The initialization control signal GI may correspond to a scan signal from another pixel driving circuit unit arranged in a previous row of the corresponding pixel driving circuit unit PC.

The fifth transistor T5, the sixth transistor T6, and the eighth transistor T8 are electrically connected to the emission control line EML and concurrently (e.g., simultaneously) turned on in response to the emission control signal EM received through the emission control line EML to form a current path so that the driving current may flow in a direction from the first voltage line VDDL to the light-emitting element LED.

The seventh transistor T7 is a second initialization transistor, which may be electrically connected to the bypass control line GBL, the second initialization voltage line VIL2, and the sixth transistor T6. The seventh transistor T7 is turned on in response to a bypass control signal GB received through the bypass control line GBL to transmit the second initialization voltage Vaint from the second initialization voltage line VIL2 to a first electrode of the light-emitting element LED to initialize the first electrode of the light-emitting element LED.

The ninth transistor T9 may be electrically connected to the bypass control line GBL, the second electrode CE2 of the storage capacitor Cst via the second node N2, and the maintenance voltage line VSL. The ninth transistor T9 may be turned on in response to the bypass control signal GB received through the bypass control line GBL and transmit a maintenance voltage VSUS to the second node N2, for example, the second electrode CE2 of the storage capacitor Cst, during an initialization section and a data write section.

The eighth transistor T8 and the ninth transistor T9 may each be electrically connected to the second node N2, for example, the second electrode CE2 of the storage capacitor Cst. In one or more embodiments, the eighth transistor T8 may be turned off and the ninth transistor T9 may be turned on during the initialization section and the data write section, and the eighth transistor T8 may be turned on and the ninth transistor T9 may be turned off during an emission section. Because the maintenance voltage VSUS is transmitted to the second node N2 during the initialization section and the data write section, the brightness uniformity (for example, long-range uniformity (LRU)) of the display apparatus according to a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9 via the second node N2.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to a voltage difference between the first electrode of the light-emitting element LED and the maintenance voltage line VSL while the seventh transistor T7 and the ninth transistor T9 are turned on, so that a problem in which black brightness increases when the sixth transistor T6 is turned off may be reduced or prevented.

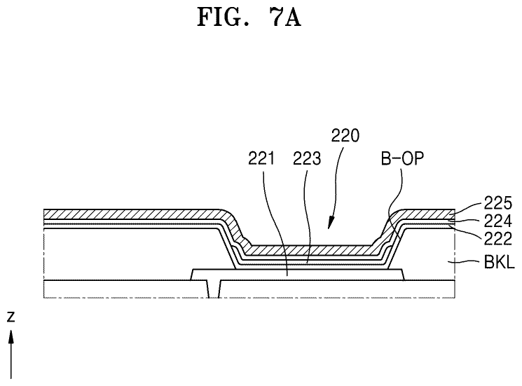

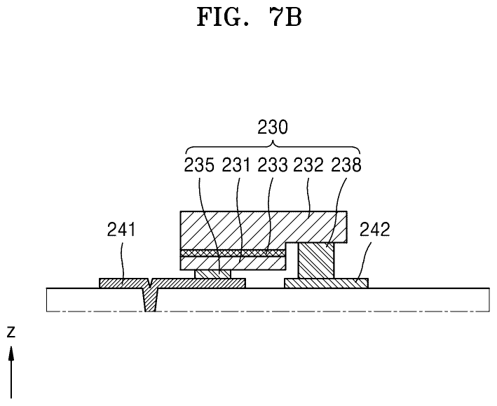

FIG. 7A is a schematic cross-sectional view of a light-emitting element of a display apparatus according to one or more embodiments.

Referring to FIG. 7A, the light-emitting element according to one or more embodiments may include an organic light-emitting diode 220 including an organic material. The organic light-emitting diode 220 may include a first electrode 221 disposed on an insulating layer, a second electrode 225 facing the first electrode 221, and an emission layer 223 arranged between the first electrode 221 and the second electrode 225. A first functional layer 222 may be arranged between the first electrode 221 and the emission layer 223, and a second functional layer 224 may be arranged between the emission layer 223 and the second electrode 225.

An edge of the first electrode 221 may be covered with a bank layer BKL including an insulating material. The bank layer BKL may include an opening B-OP overlapping the central portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 221 may include a reflective layer including silver (Ag), magnesium (Mg), aluminum (AI), platinum (Pt), palladium (Pd), gold (Au), nickel (Ni), neodymium (Nd), iridium (Ir), chromium (Cr), and/or a compound thereof. In one or more other embodiments, the first electrode 221 may further include a layer including ITO, IZO, ZnO, and/or In₂O₃ above/below the reflective layer stated above.

The emission layer 223 may include a polymer organic material or a low-molecular-weight organic material, which emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a (semi) transparent layer including Ag, Mg, Al, Pt, Pd, Au, Ni, Nd, Ir, Cr, lithium (Li), calcium (Ca), alloys thereof, and/or the like. Alternatively, the second electrode 225 may further include a layer, such as ITO, IZO, ZnO, and/or In₂O₃, above the (semi) transparent layer including the above-stated material.

FIG. 7B is a schematic cross-sectional view of a light-emitting element of a display apparatus according to one or more embodiments.

Referring to FIG. 7B, the light-emitting element according to one or more embodiments may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may respectively be electrically connected to a first electrode pad 241 and a second electrode pad 242, which are disposed on (e.g., at) the same layer.

In one or more embodiments, the first semiconductor layer 231 may include a p-type semiconductor layer. The p-type semiconductor layer is a semiconductor material with a composition formula of InxAlyGa1-x-yN (0≤x≤1, 0≤y≤1, 0≤x+y≤1), which may, for example, be selected from among GaN, AlN, AlGaN, InGaN, InN, InAlGaN, AlInN, and/or the like, and may be doped with a p-type dopant such as Mg, Zn, Ca, Sr, Ba, and/or the like.

The second semiconductor layer 232 may include, for example, an n-type semiconductor layer. The n-type semiconductor layer is a semiconductor material having a composition formula of InxAlyGa1-x-yN (0≤x≤1, 0≤y≤1, 0≤x+y≤1), which may, for example, be selected from among GaN, AlN, AlGaN, InGaN, InN, InAlGaN, AlInN, and/or the like, and may be doped with an n-type dopant such as Si, Ge, Sn, and/or the like.

The intermediate layer 233 is a region where electrons and holes are recombined. As the electrons and holes are recombined, the intermediate layer 233 may transition to a low energy level and generate light having a corresponding wavelength. For example, the intermediate layer 233 may be formed by including a semiconductor material having a composition formula of InxAlyGa1-x-yN (0≤x≤1, O≤y≤1, 0≤x+y≤1), and may be formed as a single-quantum well structure or a multi-quantum well (MQW) structure. In addition, the intermediate layer 233 may also include a quantum wire structure or a quantum dot structure.

FIG. 7B shows that the first semiconductor layer 231 includes a p-type semiconductor layer, and the second semiconductor layer 232 includes an n-type semiconductor layer, but the present disclosure is not limited thereto. In one or more embodiments, the first semiconductor layer 231 may include an n-type semiconductor layer, and the second semiconductor layer 232 may include a p-type semiconductor layer.

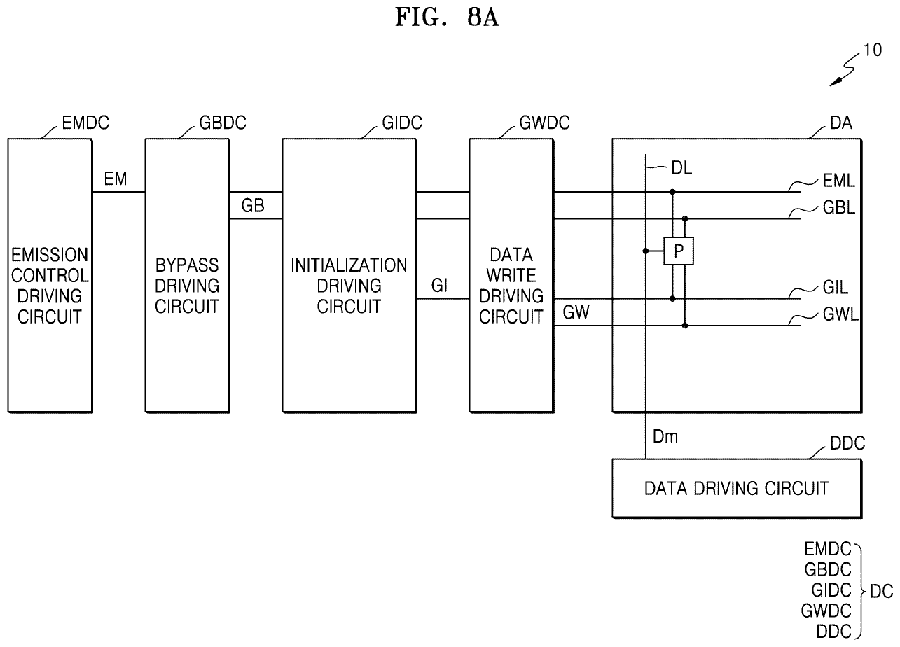

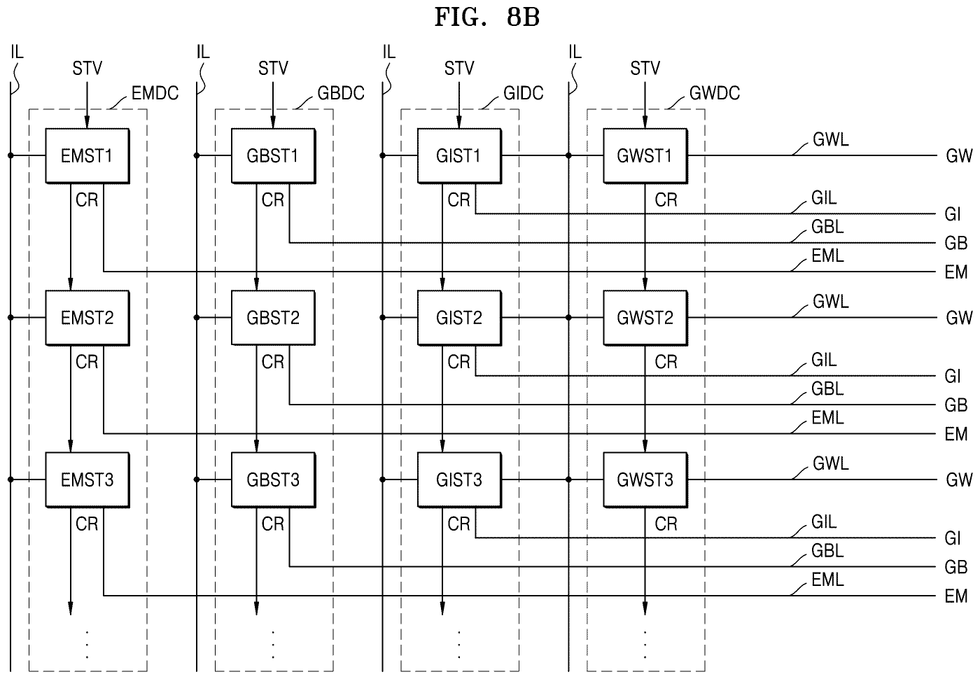

FIG. 8A is a schematic configuration diagram of a display apparatus according to one or more embodiments.

Referring to FIG. 8A, a plurality of sub-pixels P and signal lines that may apply electrical signals to the plurality of sub-pixels P may be positioned in the display area DA. The signal lines that may respectively apply electrical signals to the sub-pixels P may include a plurality of data lines DL, a plurality of emission control lines EML, a plurality of scan signal lines GWL, a plurality of initialization control lines GIL, and a plurality of bypass control lines GBL.

A driving circuit DC supplying signals for driving the sub-pixels P may be positioned outside the display area DA. The driving circuit DC may include a data driving circuit DDC and the gate driving circuit GDC (refer to FIG. 3), and the gate driving circuit GDC (refer to FIG. 3) may include an emission control driving circuit EMDC, a bypass driving circuit GBDC, an initialization driving circuit GIDC, and a data write driving circuit GWDC. The data driving circuit DDC may be arranged adjacent to the lower side surface of the display area DA to be connected to the data lines DL and output the data signal Dm with the data lines DL.

The emission control driving circuit EMDC, the bypass driving circuit GBDC, the initialization driving circuit GIDC, and the data write driving circuit GWDC may be arranged adjacent to the left side surface or the right side surface of the display area DA. The emission control driving circuit EMDC may be connected to the emission control lines EML and output the emission control signal EM via the emission control lines EML. The bypass driving circuit GBDC may be connected to the bypass control lines GBL and output the bypass control signal GB via the bypass control lines GBL. The initialization driving circuit GIDC may be connected to the initialization control lines GIL and output the initialization control signal GI via the initialization control lines GIL. The data write driving circuit GWDC may be connected to the scan signal lines GWL to output the scan signal GW.

FIG. 8B is a schematic diagram illustrating a gate driving circuit according to one or more embodiments. FIG. 8B is a diagram illustrating the schematic configurations of the emission control driving circuit EMDC, the bypass driving circuit GBDC, the initialization driving circuit GIDC, and the data write driving circuit GWDC.

Referring to FIG. 8B, the emission control driving circuit EMDC may be implemented as a shift register including a plurality of emission control stages (e.g., a first emission control stage EMST1, a second emission control stage EMST2, a third emission control stage EMST3, . . . ). Each of the emission control stages (e.g., the first emission control stage EMST1, the second emission control stage EMST2, the third emission control stage EMST3, . . . ) may be a sub-driving circuit. Each of the emission control stages (e.g., the first emission control stage EMST1, the second emission control stage EMST2, the third emission control stage EMST3, . . . ) may be connected to a corresponding emission control line EML and output the emission control signal EM via the corresponding emission control line EML. The first emission control stage EMST1 may output the emission control signal EM in response to an external start signal STV, and each of the remaining emission control stages (e.g., the second emission control stage EMST2, the third emission control stage EMST3, . . . ) except the first emission control stage EMST1 may receive a carry signal CR output from the previous stage as a start signal. Each of the emission control stages (e.g., the first emission control stage EMST1, the second emission control stage EMST2, the third emission control stage EMST3, . . . ) may be connected to a plurality of input lines IL arranged outside the emission control stages (e.g., the first emission control stage EMST1, the second emission control stage EMST2, the third emission control stage EMST3, . . . ).

The bypass driving circuit GBDC may be implemented as a shift register including a plurality of bypass stages (e.g., a first bypass stage GBST1, a second bypass stage GBST2, a third bypass stage GBST3, . . . ). Each of the bypass stages (e.g., the first bypass stage GBST1, the second bypass stage GBST2, the third bypass stage GBST3, . . . ) may be a sub-driving circuit. Each of the bypass stages (e.g., the first bypass stage GBST1, the second bypass stage GBST2, the third bypass stage GBST3, . . . ) may be connected to a corresponding bypass control line GBL and output the bypass control signal GB via the corresponding bypass control line GBL. The first bypass stage GBST1 may output the bypass control signal GB in response to the external start signal STV, and each of the remaining bypass stages (e.g., the second bypass stage GBST2, the third bypass stage GBST3, . . . ) except the first bypass stage GBST1 may receive the carry signal CR output from the previous stage as a start signal. Each of the bypass stages (e.g., the first bypass stage GBST1, the second bypass stage GBST2, the third bypass stage GBST3, . . . ) may be connected to the plurality of input lines IL arranged outside the bypass stages (e.g., the first bypass stage GBST1, the second bypass stage GBST2, the third bypass stage GBST3, . . . ).

The initialization driving circuit GIDC may be implemented as a shift register including a plurality of initialization stages (e.g., a first initialization stage GIST1, a second initialization stage GIST2, a third initialization stage GIST3, . . . ). Each of the initialization stages (e.g., the first initialization stage GIST1, the second initialization stage GIST2, the third initialization stage GIST3, . . . ) may be a sub-driving circuit. Each of the initialization stages (e.g., the first initialization stage GIST1, the second initialization stage GIST2, the third initialization stage GIST3, . . . ) may be connected to a corresponding initialization control line GIL and output the initialization control signal GI via the corresponding initialization control line GIL. The first initialization stage GIST1 may output the initialization control signal GI in response to the external start signal STV, and each of the remaining initialization stages (e.g., the second initialization stage GIST2, the third initialization stage GIST3, . . . ) except the first initialization stage GIST1 may receive the carry signal CR output from the previous stage as a start signal. Each of the initialization stages (e.g., the first initialization stage GIST1, the second initialization stage GIST2, the third initialization stage GIST3, . . . ) may be connected to the plurality of input lines IL arranged outside the initialization stages (e.g., the first initialization stage GIST1, the second initialization stage GIST2, the third initialization stage GIST3, . . . ).

The data write driving circuit GWDC may be implemented as a shift register including a plurality of data write stages (e.g., a first data write stage GWST1, a second data write stage GWST2, a third data write stage GWST3, . . . ). Each of the data write stages (e.g., the first data write stage GWST1, the second data write stage GWST2, the third data write stage GWST3, . . . ) may be a sub-driving circuit. Each of the data write stages (e.g., the first data write stage GWST1, the second data write stage GWST2, the third data write stage GWST3, . . . ) may be connected to a corresponding scan signal line GWL and output the scan signal GW via the corresponding scan signal line GWL. The first data write stage GWST1 may output the scan signal GW in response to the external start signal STV, and each of the remaining data write stages (e.g., the second data write stage GWST2, the third data write stage GWST3, . . . ) except the first data write stage GWST1 may receive the carry signal CR output from the previous stage as a start signal. Each of the data write stages (e.g., the first data write stage GWST1, the second data write stage GWST2, the third data write stage GWST3, . . . ) may be connected to the plurality of input lines IL arranged outside the data write stages (e.g., the first data write stage GWST1, the second data write stage GWST2, the third data write stage GWST3, . . . ).

The plurality of input lines IL may be signal lines including a plurality of voltage lines and a plurality of clock lines. FIG. 8B only shows one input line for convenience of illustration. The plurality of input lines IL may include a gate high voltage line, a gate low voltage line, an initiation signal line, a first clock line, a second clock line, a carry line, and a reset signal line.

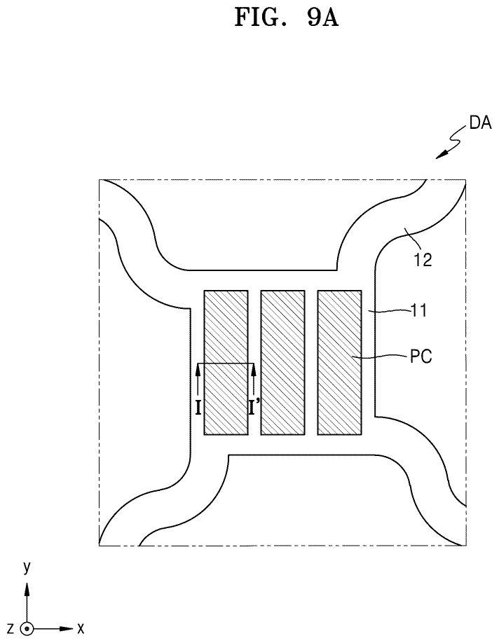

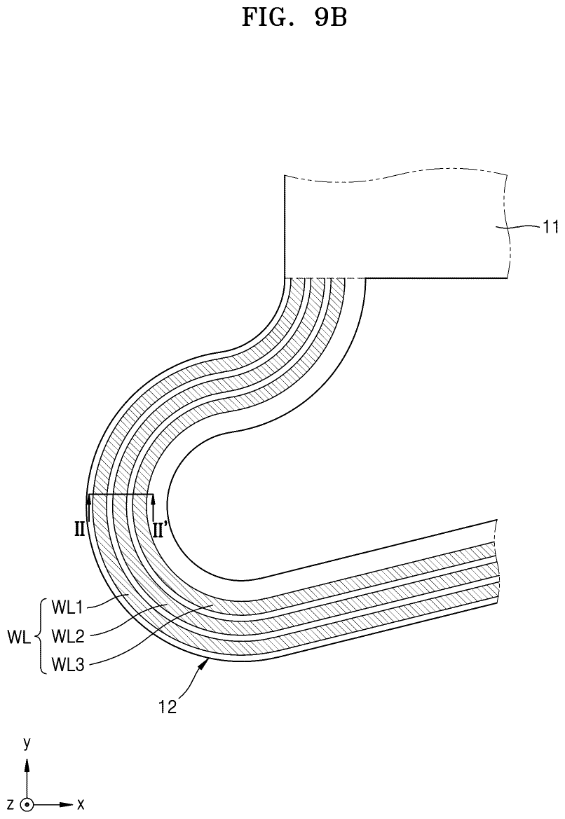

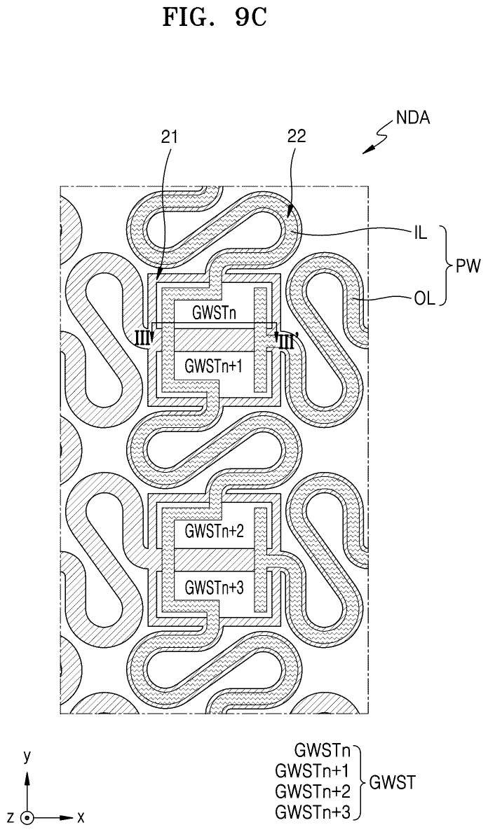

FIG. 9A is an enlarged plan view of a main island portion of a display apparatus according to one or more embodiments, and FIG. 9B is an enlarged plan view of the arrangement of lines on the main island portion of the display apparatus according to one or more embodiments. FIG. 9C is an enlarged plan view of a peripheral island portion and a peripheral bridge portion of a display apparatus according to one or more embodiments.

Referring to FIG. 9A, the main island portion 11 arranged in the display area DA may include light-emitting elements and the pixel driving circuit unit PC electrically connected to the light-emitting element. The pixel driving circuit unit PC may include transistors and at least one capacitor, as described above. FIG. 9A shows three pixel driving circuit units PC arranged in the main island portion 11, but the present disclosure is not limited thereto. In one or more embodiments, the number of pixel driving circuit units PC and the number of light-emitting elements, which are arranged in the main island portion 11, may be one, two, or four or more.

Referring to FIG. 9B, the main bridge portion 12 may include a plurality of connection lines WL electrically connected to the pixel driving circuit units PC arranged in adjacent main island portions 11, respectively. As described above, the connection lines WL may be signal lines for providing electrical signals or voltage lines for providing voltages to the transistors in the pixel driving circuit unit PC of the main island portion 11. For example, the connection lines WL may include at least one of the data line DL (refer to FIG. 8A), the scan signal line GWL (refer to FIG. 8B), the bypass control line GBL (refer to FIG. 8B), the initialization control line GIL (refer to FIG. 8B), and/or the emission control line EML (refer to FIG. 8B). Alternatively, the connection lines WL may include at least one of the first voltage line VDDL (refer to FIG. 6B), the second voltage line VSSL (refer to FIG. 6B), the first initialization voltage line VIL1 (refer to FIG. 6B), and/or the second initialization voltage line VIL2 (refer to FIG. 6B). FIG. 9B shows that the plurality of connection lines WL, for example, first to third connection lines WL1, WL2, and WL3, are disposed on the main bridge portion 12, but the present disclosure is not limited thereto. In one or more embodiments, one connection line WL may also be disposed on the main bridge portion 12, or four or more connection lines WL may be disposed.

Referring to FIG. 9C, the peripheral island portion 21 and the peripheral bridge portion 22 may be arranged in the non-display area NDA. A plurality of peripheral island portions 21 may be arranged to be spaced (e.g., spaced apart) from each other, and the peripheral bridge portion 22 may connect adjacent peripheral island portions 21 to each other. The gate driving circuit GDC (refer to FIG. 3) and a plurality of peripheral lines PW may be disposed on the peripheral island portion 21 and the peripheral bridge portion 22.

As described above, the gate driving circuit GDC (refer to FIG. 3) may include the emission control driving circuit EMDC (refer to FIG. 8A), the bypass driving circuit GBDC (refer to FIG. 8A), the initialization driving circuit GIDC (refer to FIG. 8A), and the data write driving circuit GWDC (refer to FIG. 8A). At this time, each driving circuit may include a plurality of driver stages. For example, the data write driving circuit GWDC may include a plurality of data write stages (for example, an n-th data write stage GWSTn, an n+1-th data write stage GWSTn+1, an n+2-th data write stage GWSTn+2, and an n+3-th data write stage GWSTn+3). As shown in FIG. 9C, the n-th data write stage GWSTn, the n+1-th data write stage GWSTn+1, the n+2-th data write stage GWSTn+2, and the n+3-th data write stage GWSTn+3 may be arranged in some of the peripheral island portions 21. At this time, each of the driver stages may include a plurality of transistors for generating output signals and a capacitor.

In addition, a plurality of peripheral lines PW may be disposed on the peripheral island portion 21 and the peripheral bridge portion 22. The peripheral line PW may be a line arranged in the non-display area NDA in which sub-pixels are not arranged. In particular, the peripheral line PW may include the driving voltage supply line W11, the common voltage supply line W13, and the fan-out line FW, as described above with reference to FIG. 3. Furthermore, the peripheral line PW may include the plurality of input lines IL for inputting signals to the gate driving circuit GDC (refer to FIG. 3) and a plurality of output lines OL for transmitting output signals generated by the gate driving circuit GDC (refer to FIG. 3).

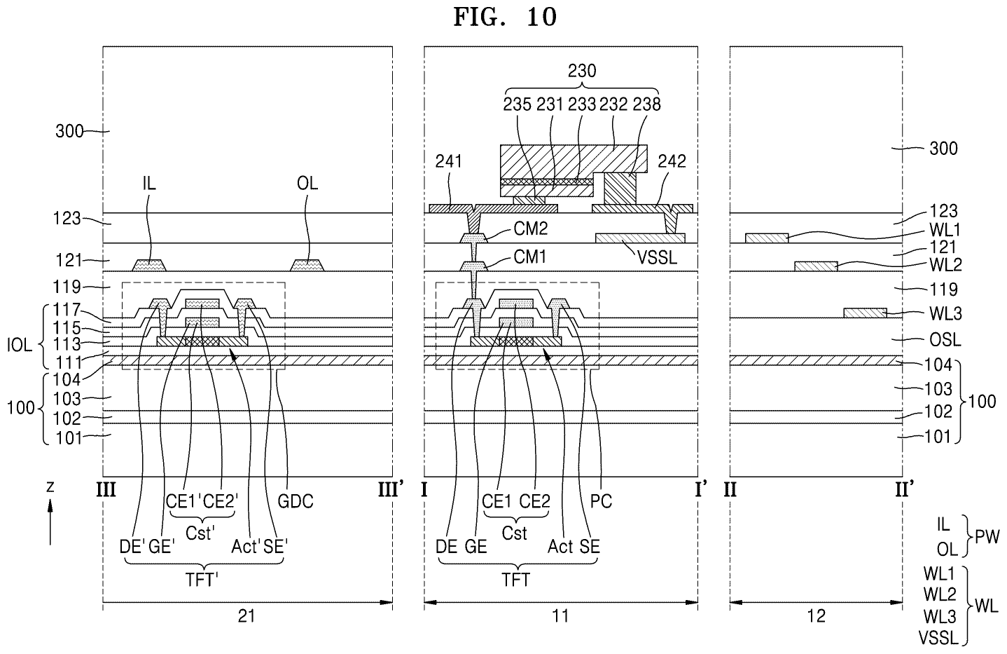

FIG. 10 shows the cross-sectional views respectively taken along the line I-I′ of FIG. 9A, the line II-II′ of FIG. 9B, and the line III-III′ of FIG. 9C.

Referring to FIG. 10, the substrate 100 corresponding to the main island portion 11 may include a first base layer 101, a first barrier layer 102, a second base layer 103, and a second barrier layer 104. Each of the first base layer 101 and the second base layer 103 may include a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, and/or the like. Each of the first barrier layer 102 and the second barrier layer 104 may include an inorganic insulating material, such as silicon oxide, silicon nitride, and/or silicon oxynitride.

The buffer layer 111 may be disposed on the substrate 100, and the pixel driving circuit unit PC (including at least the thin-film transistor TFT and the capacitor Cst) may be disposed on the buffer layer 111. The buffer layer 111 may include an inorganic insulating material, such as silicon oxide, silicon nitride, and/or silicon oxynitride.

A thin-film transistor TFT may include a first semiconductor layer Act, a first gate electrode GE, a first source electrode SE, and a first drain electrode DE. FIG. 10 shows a top-gate type in which the first gate electrode GE is disposed on the first semiconductor layer Act with a gate insulating layer 113 therebetween, but according to one or more other embodiments, the thin-film transistor TFT may be a bottom-gate type.

The first semiconductor layer Act may include polysilicon. Alternatively, the first semiconductor layer Act may include amorphous silicon, an oxide semiconductor, an organic semiconductor, and/or the like. The first gate electrode GE may include a metal thin film including a low-resistance metal material. The first gate electrode GE may include a conductive material including molybdenum (Mo), Al, copper (Cu), titanium (Ti), and/or the like, and may be formed as a single layer or a multi-layer, each including the above material. For example, the first gate electrode GE may include a metal thin film including a triple layer of a Ti/Al/Ti structure.

The gate insulating layer 113 between the first semiconductor layer Act and the first gate electrode GE may include an inorganic insulating material, such as silicon oxide, silicon nitride, silicon oxynitride, aluminum oxide, and/or titanium oxide. The gate insulating layer 113 may be a single layer or a multi-layer, each including the material described above. The gate insulating layer 113 may be disposed on the buffer layer 111 and the first semiconductor layer Act. The first gate electrode GE of the thin-film transistor TFT may be disposed on the gate insulating layer 113 overlapping the first semiconductor layer Act. The first gate electrode GE may be a first electrode CE1 of a first storage capacitor Cst. A first interlayer insulating layer 115 may be disposed on the gate insulating layer 113 and the first gate electrode GE. A second electrode CE2 of the first storage capacitor Cst may be disposed on the first interlayer insulating layer 115. A second interlayer insulating layer 117 may be disposed on the first interlayer insulating layer 115 and the second electrode CE2 of the first storage capacitor Cst.

The first source electrode SE and the first drain electrode DE may be positioned on (e.g., at) the same layer, for example, the second interlayer insulating layer 117, and may include the same material. The first source electrode SE and the first drain electrode DE may be connected to the first semiconductor layer Act via respective contact holes penetrating the gate insulating layer 113, the first interlayer insulating layer 115, and the second interlayer insulating layer 117. The first source electrode SE and the first drain electrode DE may each include a metal thin film including a low-resistance metal material. The first source electrode SE and the first drain electrode DE may include a conductive material including Mo, Al, Cu, Ti, and/or the like, and may be formed as a multi-layer or a single layer, each including the above material. For example, similar to the first gate electrode GE, each of the first source electrode SE and the first drain electrode DE may include a metal thin film including a triple layer of a Ti/Al/Ti structure. The second interlayer insulating layer 117 may include an inorganic insulating material, such as silicon oxide, silicon nitride, silicon oxynitride, aluminum oxide, and titanium oxide, and/or may be a single layer or a multi-layer, each including the material described above.

The first storage capacitor Cst may include the first electrode CE1 and the second electrode CE2, which overlap each other with the first interlayer insulating layer 115 therebetween. The first storage capacitor Cst may overlap the thin-film transistor TFT. In this regard, FIG. 10 shows that the first gate electrode GE of the thin-film transistor TFT is the first electrode CE1 of the first storage capacitor Cst. In one or more embodiments, the first storage capacitor Cst may not overlap the thin-film transistor TFT. The first storage capacitor Cst may be covered with the second interlayer insulating layer 117.

The first interlayer insulating layer 115 may be arranged between the gate insulating layer 113 and the second interlayer insulating layer 117. The first interlayer insulating layer 115 may include an inorganic insulating material, such as silicon oxide, silicon nitride, silicon oxynitride, aluminum oxide, and/or titanium oxide, and may be a single layer or a multi-layer, each including the material described above.

The second electrode CE2 of the first storage capacitor Cst may include a conductive material and may be formed as a multi-layer or a single layer. The second electrode CE2 may include a metal thin film including a low-resistance metal material. The second electrode CE2 may include a conductive material including Mo, Al, Cu, Ti, and/or the like, and may be formed as a multi-layer or a single layer, each including the above material. For example, the second electrode CE2 may include a metal thin film including a triple layer of a Ti/Al/Ti structure.

An inorganic insulating material layer IOL on the substrate 100 may include, for example, the buffer layer 111, the gate insulating layer 113, the first interlayer insulating layer 115, and the second interlayer insulating layer 117.

A first organic insulating layer 119 may be disposed on the second interlayer insulating layer 117, the first source electrode SE, and the first drain electrode DE. A second organic insulating layer 121 may be disposed on the first organic insulating layer 119. Each of the first organic insulating layer 119 and the second organic insulating layer 121 may include an organic insulating layer, such as polyimide.

A first connection electrode CM1 may be disposed on the first organic insulating layer 119, and a second connection electrode CM2 may be disposed on the second organic insulating layer 121. The first connection electrode CM1 and the second connection electrode CM2 may electrically connect the thin-film transistor TFT to the inorganic light-emitting diode 230. The first connection electrode CM1 may be connected to the first source electrode SE or the first drain electrode DE via a contact hole penetrating the first organic insulating layer 119. The second connection electrode CM2 may be connected to first connection electrode CM1 via a contact hole penetrating through the second organic insulating layer 121. Each of the first connection electrode CM1 and the second connection electrode CM2 may include a metal thin film including a low-resistance metal material. Each of the first connection electrode CM1 and the second connection electrode CM2 may include a conductive material including Mo, Al, Cu, Ti, and/or the like, and may be formed as a multi-layer or a single layer, each including the above material. For example, each of the first connection electrode CM1 and the second connection electrode CM2 may include a metal thin film including a triple layer of a Ti/Al/Ti structure.

The second voltage line VSSL may be disposed on the second organic insulating layer 121, and a third organic insulating layer 123 may be disposed on the second organic insulating layer 121 and the second voltage line VSSL. The third organic insulating layer 123 may include an organic insulating layer, such as polyimide. The second voltage line VSSL may be connected to the common voltage supply line W13 (refer to FIG. 3) to transmit the second power supply voltage VSS (refer to FIG. 6A) to the second electrode 238 of the inorganic light-emitting diode 230. The second voltage line VSSL may include a conductive material and may be formed as a multi-layer or a single layer. However, at this time, the second voltage line VSSL may include a material different from that of the second connection electrode CM2 disposed on (e.g., at) the same layer as the second voltage line VSSL. The material of the second voltage line VSSL is described in more detail below.

The first electrode pad 241 and the second electrode pad 242 may be disposed on the third organic insulating layer 123. The first electrode pad 241 may be electrically connected to the thin-film transistor TFT through the first connection electrode CM1 between the first organic insulating layer 119 and the second organic insulating layer 121 and the second connection electrode CM2 between the second organic insulating layer 121 and the third organic insulating layer 123. The inorganic light-emitting diode 230 on the first electrode pad 241 and the second electrode pad 242 is as described above with reference to FIG. 7B. A light-emitting diode, for example, the inorganic light-emitting diode 230, may be protected with the encapsulation layer 300, and the encapsulation layer 300 may include an inorganic encapsulation layer and/or an organic encapsulation layer, or an organic material such as resin. FIG. 10 shows that the light-emitting diode is the inorganic light-emitting diode 230 described above with reference to FIG. 7B, but in one or more other embodiments, the light-emitting diode may be the organic light-emitting diode 220 described above with reference to FIG. 7A.

To summarize, the thin-film transistor TFT included in the pixel driving circuit unit PC may include a plurality of conductive layers. In particular, the plurality of conductive layers included in the thin-film transistor TFT may include the first gate electrode GE, the first source electrode SE, the first drain electrode DE, and the first electrode CE1 and the second electrode CE2 of the first storage capacitor Cst. The plurality of conductive layers included in the thin-film transistor TFT, the first connection electrode CM1, and the second connection electrode CM2, may each include a material of a metal thin film. For example, the plurality of conductive layers included in the thin-film transistor TFT, the first connection electrode CM1, and the second connection electrode CM2 may each include a metal thin film including a triple layer of a Ti/Al/Ti structure. Accordingly, the modulus of each of the plurality of conductive layers included in the thin-film transistor TFT, the first connection electrode CM1, and the second connection electrode CM2 may be greater than 100 gigapascal (GPa) and less than 1000 GPa. In other words, the modulus of the conductive layers of the thin-film transistor TFT may be greater than the modulus of each of the connection line WL and the peripheral line PW to be described below.

Next, referring to the main bridge portion 12 of FIG. 10, the substrate 100 corresponding to the main bridge portion 12 may have the same stacked structure as the substrate 100 corresponding to the main island portion 11. In one or more embodiments, the substrate 100 corresponding to the main bridge portion 12 may include the first base layer 101, the first barrier layer 102, the second base layer 103, and the second barrier layer 104. In one or more embodiments, the substrate 100 corresponding to the main bridge portion 12 may have a stacked structure different from that of the substrate 100 corresponding to the main island portion 11. The substrate 100 corresponding to the main bridge portion 12 may have the structure of the first base layer 101 and the second base layer 103.

The inorganic insulating material layer IOL may not be disposed on the substrate 100 of the main bridge portion 12, and an insulating layer OSL, the first organic insulating layer 119, the second organic insulating layer 121, and the third organic insulating layer 123 may be disposed on the substrate 100. The insulating layer OSL may include an organic insulating material, such as polyimide. In one or more embodiments, the insulating layer OSL may have a thickness corresponding to the inorganic insulating material layer IOL. In one or more embodiments, the insulating layer OSL may be omitted.

A plurality of connection lines WL may be disposed on the main bridge portion 12. The plurality of connection lines WL, for example, the first to third connection lines WL1, WL2, and WL3, may be disposed on different layers but may be electrically connected to the same pixel driving circuit unit PC. For example, the first connection line WL1 may be arranged between the second organic insulating layer 121 and the third organic insulating layer 123, the second connection line WL2 may be arranged between the first organic insulating layer 119 and the second organic insulating layer 121, and the third connection line WL3 may be arranged between the insulating layer OSL and the first organic insulating layer 119. However, the present disclosure is not limited thereto, and in one or more embodiments, at least some of the first to third connection lines WL1, WL2, and WL3 may be disposed on (e.g., at) the same layer.

At this time, the plurality of connection lines WL may be signal lines for providing electrical signals or voltage lines for providing voltages to the thin-film transistor TFT included in the pixel driving circuit unit PC. For example, the connection lines WL may include at least one of the data line DL (e.g., refer to FIG. 8A), the scan signal line GWL (e.g., refer to FIG. 8B), the bypass control line GBL (e.g., refer to FIG. 8B), the initialization control line GIL (e.g., refer to FIG. 8B), and/or the emission control line EML (e.g., refer to FIG. 8B). Alternatively, the connection lines WL may include at least one of the first voltage line VDDL (e.g., refer to FIG. 6B), the second voltage line VSSL, the first initialization voltage line VIL1 (e.g., refer to FIG. 6B), the second initialization voltage line VIL2 (e.g., refer to FIG. 6B), and/or the maintenance voltage line VSL.

However, even when the plurality of connection lines WL are disposed on (e.g., at) the same layer as the conductive layers of the thin-film transistor TFT, the first connection electrode CM1, and the second connection electrode CM2, the plurality of connection lines WL may include a material different from the materials of the conductive layers of the thin-film transistor TFT, the first connection electrode CM1, and the second connection electrode CM2. In one or more embodiments, the plurality of connection lines WL may each include a material having a lower modulus than the modulus of each of the conductive layers of the thin-film transistor TFT, the first connection electrode CM1, and the second connection electrode CM2. For example, the modulus of each of the plurality of connection lines WL may be greater than 1 MPa and less than 100 MPa.

In particular, the plurality of connection lines WL may each include a metal nanostructure and an elastic polymer. The metal nanostructure is, for example, a nano-level structure including an inorganic material, an organic material, or organic and inorganic materials, which may be a nanostructure having a one-dimensional, two-dimensional, and/or three-dimensional shape. The metal nanostructure may include, for example, a nanoparticle, a nano-rod, a nano-plate, a nano-wire, a nanoflake, a nano-tube, a nano-capsule, and/or a combination thereof, but is not limited thereto. For example, the metal nanostructure may be an inorganic nanoparticle, an inorganic nano-rod, an inorganic nano-plate, an inorganic nanoflake, an inorganic nano-tube, an inorganic nano-capsule, and/or a combination thereof, but is not limited thereto.

The metal nanostructure may be, for example, an oxide, a nitride, and/or an oxynitride, and may be, for example, a metal oxide, a metalloid oxide, a metal nitride, a metalloid nitride, a metal oxynitride, and/or a metalloid oxynitride. In one or more embodiments, the metal nanostructure may include at least one of an Ag nanoparticle, an Ag nanoflake, and/or an Ag nanowire.

The metal nanostructure may have, for example, a major axis of about 200 nm or less, for example, a major axis of about 5 nm to about 100 nm, a major axis of about 5 nm to about 80 nm, and a major axis of about 5 nm to about 50 nm. Here, the major axis may be a diameter in the case of a spherical shape, and may be the longest part from among a height, width, and thickness in the case of non-spherical shapes.

The elastic polymer may include at least one of polydimethylsiloxane (PDMS), polyurethane (PU), and/or Ecoflex. However, the present disclosure is not limited thereto, and the elastic polymer may be a material that is easy to complex with the metal nanostructure.

Each of the plurality of connection lines WL may further include other conductive additives in addition to the metal nanostructure and the elastic polymer. In one or more embodiments, each of the plurality of connection lines WL may further include a carbon-based material including carbon nanotubes (CNT), carbon fibers, graphene, graphene oxide, and/or any combination thereof. In one or more embodiments, the concentration of the metal nanostructure in each of the plurality of connection lines WL may be about 60 wt % to about 80 wt %, and the concentration of the carbon-based material of each of the plurality of connection lines WL may be about 1 wt % to about 10 wt %. Accordingly, the minimum electrical conductivity of the plurality of connection lines WL may satisfy the level of 10⁻³ Ω·cm.

Next, referring to the peripheral island portion 21 of FIG. 10, the gate driving circuit GDC and the plurality of peripheral lines PW (IL, OL) may be disposed on the peripheral island portion 21. The substrate 100 corresponding to the peripheral island portion 21 may have the same stacked structure as the substrate 100 corresponding to the main island portion 11. The buffer layer 111 may be disposed on the substrate 100, and the gate driving circuit GDC may be disposed on the buffer layer 111.

The gate driving circuit GDC may include a plurality of driver stages, and each of the plurality of driver stages may include a plurality of transistors and a capacitor. For example, the gate driving circuit GDC may include a peripheral thin-film transistor TFT′, as shown in FIG. 10. The peripheral thin-film transistor TFT′ may include a second semiconductor layer Act′, a second gate electrode GE′, a second source electrode SE′, a second drain electrode DE′, and a second storage capacitor Cst′. Similar to the first semiconductor layer Act, the second semiconductor layer Act′ may include polysilicon, amorphous silicon, an oxide semiconductor, an organic semiconductor, and/or the like.

Conversely, although the second gate electrode GE′ may be disposed on the gate insulating layer 113, similar to the first gate electrode GE, the second gate electrode GE′ may have a material different from that of the first gate electrode GE. In one or more embodiments, the second gate electrode GE′ may include a material having a smaller modulus than that of the first gate electrode GE and the connection line WL. For example, the modulus of the second gate electrode GE′ may be greater than 1 kilopascal (kPa) and less than 100 kPa.

In particular, the second gate electrode GE′ may include a liquid metal. In one or more embodiments, the second gate electrode GE′ may include a liquid metal including a eutectic gallium-indium alloy (EGaIn) and/or a gallium-indium-tin alloy (Galinstan). That is, the second gate electrode GE′ may include at least one of gallium (Ga), indium (In), and/or tin (Sn). In particular, in the case of a eutectic Ga—In alloy, which is a eutectic alloy of Ga and In, the melting point thereof is lower than room temperature, and thus the eutectic Ga—In alloy may remain in a liquid state at room temperature and have low specific resistance.

Similarly, a second electrode CE2′ of the second storage capacitor Cst′, the second source electrode SE′, and the second drain electrode DE′ may include the same material as the second gate electrode GE′. In particular, the second electrode CE2′ of the second storage capacitor Cst′, the second source electrode SE′, and the second drain electrode DE′ may each include a liquid metal. In one or more embodiments, each of the second electrode CE2′ of the second storage capacitor Cst′, the second source electrode SE′, and the second drain electrode DE′ may include a liquid metal including an EGaIn and/or a Galinstan. In other words, the second electrode CE2′ of the second storage capacitor Cst′ is disposed on the first interlayer insulating layer 115, but may include a material having a smaller modulus than that of the second electrode CE2 of the first storage capacitor Cst and the connection line WL. Each of the second source electrode SE′ and the second drain electrode DE′ are disposed on the second interlayer insulating layer 117, but may include a material having a smaller modulus than that of the first source electrode SE, the first drain electrode DE, and the connection line WL.

The first organic insulating layer 119 may be disposed on the peripheral thin-film transistor TFT′, and the plurality of peripheral lines PW may be disposed on the first organic insulating layer 119. For example, as shown in FIG. 10, an input line IL transmitting electrical signals to the gate driving circuit GDC and an output line OL transmitting output signals from the gate driving circuit GDC may be disposed on the first organic insulating layer 119. In addition, in one or more embodiments, the driving voltage supply line W11 and the common voltage supply line W13, which may be included in the peripheral line PW, may also be disposed on the first organic insulating layer 119 and the second organic insulating layer 121.

At this time, the plurality of peripheral lines PW may each include a material having a smaller modulus than the modulus of each of the conductive layers of the thin-film transistor TFT and the connection line WL, similar to the conductive layers of the peripheral thin-film transistor TFT′. In particular, the plurality of peripheral lines PW may each include a liquid metal. In one or more embodiments, each of the plurality of peripheral lines PW may include a liquid metal including EGaIn and/or Galinstan.

To summarize, the conductive layers included in the thin-film transistor TFT of the pixel driving circuit unit PC may each include a metal thin film, the connection line WL may include a composite material of a metal nanostructure and an elastic polymer, and the peripheral line PW and the conductive layers of the peripheral thin-film transistor TFT′ may each include a liquid metal. Accordingly, the modulus of each of the conductive layers included in the thin-film transistor TFT of the pixel driving circuit unit PC may be greater than the modulus of the connection line WL, and the modulus of each of the connection lines WL may be greater than the modulus of each of the peripheral line PW and the conductive layers included in the peripheral thin-film transistor TFT′. For example, the modulus of each of the conductive layers included in the thin-film transistor TFT may have a difference of about 100 to about 1000 times the modulus of the connection line WL, and the modulus of the connection line WL may have a difference of about 100 to about 1000 times the modulus of each of the peripheral line PW and the conductive layers of the peripheral thin-film transistor TFT′.

Generally, the larger the modulus of a material layer, the better the recovery rate of the material layer, and the smaller the modulus, the better the elongation rate of the material layer. At this time, because the connection line WL has a smaller modulus than the conductive layers included in the thin-film transistor TFT, the connection line WL may have relatively excellent stretchability compared to the conductive layers included in the thin-film transistor TFT. Similarly, because the modulus of each of the conductive layers included in the peripheral thin-film transistor TFT′ and the peripheral line PW is smaller than the modulus of the connection line WL, the conductive layers included in the peripheral thin-film transistor TFT′ and the peripheral line PW have relatively excellent stretchability compared to the connection line WL.

In the case of the display apparatus 1 that is stretchable, when the display apparatus 1 is stretched, high stress may be formed at the outer portion of the display apparatus 1, and low stress may be formed at the central portion of the display apparatus 1. At this time, like the display apparatus 1 according to one or more embodiments, when a line including a material with a low modulus is formed in the non-display area NDA corresponding to the outer portion of the display apparatus 1, and a line having a material with a high modulus is formed in the pixel driving circuit unit PC of the display area DA, the transformation of the display area DA may be reduced when stress is applied, thereby securing the stability of the devices in the display apparatus. In particular, as a material with a low modulus and excellent stretchability, such as a liquid metal, is arranged in the non-display area NDA where high stress is formed, high stress may be relieved, and a material with a high modulus and excellent recovery rate and electrical characteristics, such as a metal thin film, may be arranged in the pixel driving circuit unit PC of the display area DA where electrical characteristics and device stability are important. In addition, as the connection line WL connecting the plurality of sub-pixels P of each other in the display area DA with the gate driving circuit GDC also includes a material having excellent stretchability and electrical characteristics, such as a composite material of a metal nanostructure and/or an elastic polymer, the stretchability and mechanical stability of the display apparatus 1 may be concurrently (e.g., simultaneously) implemented.

In addition, in one or more embodiments, even when all of the conductive layers of the thin-film transistor TFT, the connection line WL, the peripheral line PW, and the conductive layers of the peripheral thin-film transistor TFT′ use the same material, the stretchability and mechanical stability of the display apparatus 1 may be concurrently (e.g., simultaneously) implemented. In particular, in one or more embodiments, all of the conductive layers of the thin-film transistor TFT, the connection line WL, the peripheral line PW, and the conductive layers of the peripheral thin-film transistor TFT′ may include metal nanostructures and elastic polymers. At this time, the metal nanostructure may include at least one of Ag nanoparticles, Ag nanoflakes, and/or Ag nanowires, and the elastic polymer may include at least one of PDMS, PU, and/or Ecoflex.

However, even when the conductive layers of the thin-film transistor TFT, the connection line WL, the peripheral line PW, and the conductive layers of the peripheral thin-film transistor TFT′ include the same material, the conductive layers of the thin-film transistor TFT, the connection line WL, the peripheral line PW, and the conductive layers of the peripheral thin-film transistor TFT′ may have different moduli. That is, although all of the conductive layers of the thin-film transistor TFT, the connection line WL, the peripheral line PW, and the conductive layers of the peripheral thin-film transistor TFT′ include the composite material of the metal nanostructure and the elastic polymer, the concentration of the metal nanostructure thereof may be different. For example, the conductive layers of the thin-film transistor TFT may have a higher concentration of metal nanostructures than that of the connection line WL, and the connection line WL may have a higher concentration of metal nanostructures than that of the peripheral line PW and the conductive layers of the peripheral thin-film transistor TFT′. Alternatively, the conductive layers of the thin-film transistor TFT may have a higher concentration of carbon-based materials than that of the connection line WL, and the connection line WL may have a higher concentration of carbon-based materials than that of the peripheral line PW and the conductive layers of the peripheral thin-film transistor TFT′. The concentration of the metal nanostructures may be adjusted within the range of about 60 wt % to about 80 wt %, and the concentration of the carbon-based materials may be adjusted within the range of about 1 wt % to about 10 wt %.

Accordingly, the modulus of each of the conductive layers of the thin-film transistor TFT may be greater than the modulus of the connection line WL, and the modulus of the connection line WL may be greater than the modulus of each of the conductive layers of the peripheral thin-film transistor TFT′ and the peripheral line PW. For example, the modulus of each of the conductive layers included in the thin-film transistor TFT may have a difference of about 100 to about 1000 times the modulus of the connection line WL, and the modulus of the connection line WL may have a difference of about 100 to about 1000 times the modulus of each of the peripheral line PW and the conductive layers of the peripheral thin-film transistor TFT′.

In one or more embodiments, that is, although all of the conductive layers of the thin-film transistor TFT, the connection line WL, the peripheral line PW, and the conductive layers of the peripheral thin-film transistor TFT′ include the composite material of the metal nanostructure and the elastic polymer, the moduli thereof may be formed differently by making differences in a heat curing and/or ultraviolet (UV) curing process. For example, in the case of the conductive layers of the thin-film transistor TFT, the modulus characteristics of the material of the conductive layers of the thin-film transistor TFT may be increased by increasing the heat curing process time and/or the UV curing process time. Similarly, in the case of the conductive layers of the peripheral thin-film transistor TFT′ and the peripheral line PW, the modulus characteristics of the material of the conductive layers of the peripheral thin-film transistor TFT′ and the peripheral line PW may be lowered by reducing the heat curing process time and/or the UV curing process time. Even through the above process modification, the modulus of the conductive layers of the thin-film transistor TFT may be formed to be greater than the modulus of the connection line WL, and the modulus of the connection line WL may be formed to be greater than the modulus of each of the conductive layers of the peripheral thin-film transistor TFT′ and the peripheral line PW.

In conclusion, in a display apparatus according to one or more embodiments, as well as a display apparatus according to one or more other embodiments, excellent stretchability and mechanical stability may be concurrently (e.g., simultaneously) secured by arranging materials having different moduli for each region.

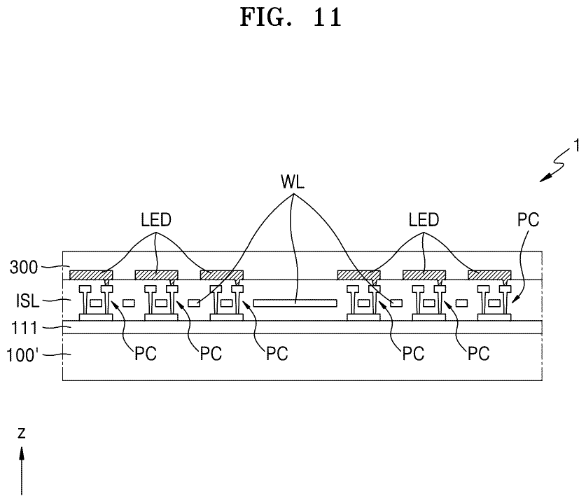

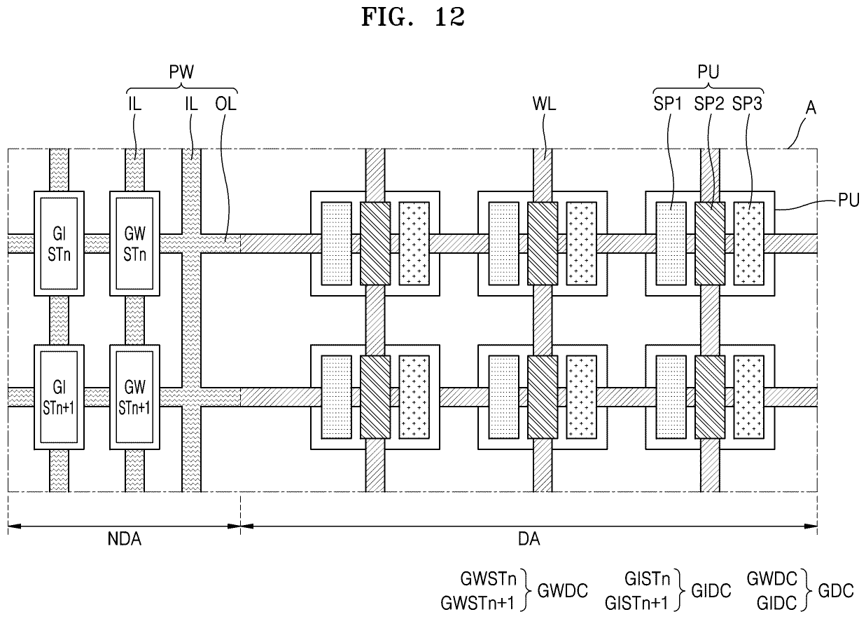

FIG. 11 is a schematic cross-sectional view of a display apparatus according to one or more embodiments. FIG. 12 is a schematic plan view of a display apparatus according to one or more other embodiments.

First, referring to FIG. 11, a substrate 100′ of the display apparatus 1 may be integrally formed without being partitioned to be spaced (e.g., spaced apart) from each other. However, the substrate 100′ may be a substrate having stretchability so that the display apparatus 1 may be stretched. For example, the substrate 100′ may include at least some stretchable areas. The stretchable area may be stretched in at least one direction by external force, and may have the property of returning to an initial state when the external force is removed. Accordingly, the stretchable area included in the substrate 100′ may be manufactured by a polymer material having certain stretchability. In particular, the substrate 100′ may include a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, and/or the like.

The buffer layer 111 may be disposed on the substrate 100′. As described above, the buffer layer 111 may include an inorganic insulating material, such as silicon oxide, silicon nitride, and/or silicon oxynitride. However, the buffer layer 111 may be omitted or include an organic insulating material for the stretchability of the display apparatus 1.

A plurality of pixel driving circuit units PC may be disposed on the buffer layer 111. An insulating layer ISL including an inorganic insulating material and/or an organic insulating material may be arranged between the pixel driving circuit unit PC and the light-emitting element LED. The light-emitting element LED may be disposed on the insulating layer ISL and may be electrically connected to a corresponding pixel driving circuit unit PC. An encapsulation layer 300 may be disposed on the light-emitting element LED and may protect the light-emitting element LED from external force and/or moisture penetration.

The plurality of pixel driving circuit units PC may be arranged to be spaced (e.g., spaced apart) from each other. At this time, the connection line WL may be arranged between the pixel driving circuit units PC, which are spaced (e.g., spaced apart) from each other. The connection line WL may be a signal line (e.g., a gate line, a data line, and/or the like) for providing electrical signals or a voltage line (e.g., a driving voltage line, an initialization voltage line, or the like) for providing voltages to a transistor included in the pixel driving circuit unit PC. At this time, the connection line WL may include a material with a lower modulus than the conductive layers arranged in the pixel driving circuit unit PC. That is, as the connection line WL includes a material with excellent stretchability, the display apparatus 1 as shown in FIG. 11 may be stretched by using the stretchability of the devices therein without being divided into an island portion and a bridge portion.

Next, referring to FIG. 12, a plurality of display units PU may be arranged in the display area DA. The display unit PU may include a first sub-pixel SP1 emitting red light, a second sub-pixel SP2 emitting green light, and a third sub-pixel SP3 emitting blue light. Neighboring display units PU may be electrically connected to each other through the connection line WL. In addition, neighboring sub-pixels P (e.g., SP1, SP2, SP3) in one display unit PU may also be electrically connected to each other through the connection line WL. However, as shown in FIG. 12, a distance between neighboring display units PU may be greater than a distance between neighboring sub-pixels P (e.g., SP1, SP2, SP3) in one display unit PU.

The gate driving circuit GDC may be arranged in the non-display area NDA. As described above, the gate driving circuit GDC may include the emission control driving circuit EMDC (refer to FIG. 8A), the bypass driving circuit GBDC (refer to FIG. 8A), the initialization driving circuit GIDC, and the data write driving circuit GWDC. Each driving circuit may include a plurality of driver stages. For example, the initialization driving circuit GIDC may include an n-th initialization stage GISTn and an n+1-th initialization stage GISTn+1, and the data write driving circuit GWDC may include the n-th data write stage GWSTn and the n+1-th data write stage GWSTn+1. Each of the driver stages may include a plurality of transistors and a capacitor.

In addition, the peripheral lines PW may be arranged in the non-display area NDA. As shown in FIG. 12, the peripheral line PW may include input lines IL which may input electrical signals to the gate driving circuit GDC and an output line OL transmitting output signals from the gate driving circuit GDC. In one or more embodiments, the peripheral line PW may also further include the driving voltage supply line W11, the common voltage supply line W13, and the fan-out line FW (e.g., see FIG. 3).

Even in the structures as shown in FIGS. 11 and 12, materials having different moduli may be respectively arranged in the display area DA and the non-display area NDA. In particular, the conductive layers arranged in the pixel driving circuit unit PC may be provided with a material having a higher modulus than the modulus of the connection line WL, and the connection line WL may be provided with a material having a higher modulus than the modulus of each of the conductive layers included in the gate driving circuit GDC and the peripheral line PW.

In one or more embodiments, the conductive layers arranged in the pixel driving circuit unit PC may each include a metal thin film. For example, each of the conductive layers arranged in the pixel driving circuit unit PC may include a metal thin film including a triple layer of a Ti/Al/Ti structure. The connection line WL may include a composite material of a metal nanostructure and an elastic polymer. For example, the metal nanostructure included in the connection line WL may include at least one of Ag nanoparticles, Ag nanoflakes, and/or Ag nanowires, and the elastic polymer may include at least one of PDMS, PU, and/or Ecoflex. The conductive layers included in the gate driving circuit GDC and the peripheral line PW may each include a liquid metal. For example, the conductive layers included in the gate driving circuit GDC and the peripheral line PW may each include a liquid metal including EGaIn and/or Galinstan.

In one or more other embodiments, although the conductive layers arranged in the pixel driving circuit unit PC, the connection line WL, the peripheral line PW, and the conductive layers arranged in the gate driving circuit GDC include the same material, the moduli thereof may be different from each other. For example, although all of the conductive layers arranged in the pixel driving circuit unit PC, the connection line WL, the peripheral line PW, and the conductive layers arranged in the gate driving circuit GDC include the composite material of the metal nanostructure and the elastic polymer, the concentrations of metal nanostructures thereof may be different from each other.

Because the display apparatus 1 shown in FIGS. 11 and 12 may be entirely stretched, the mechanical stability of the transistors included in the pixel driving circuit unit PC and the stretchability of other connection lines WL and the peripheral lines PW may be required at the same time. Accordingly, in the display apparatus according to one or more other embodiments, the conductive layers included in the pixel driving circuit unit PC include a material with a higher modulus and excellent recovery rate than that of the connection line WL, and thus the stability and electrical characteristics of the transistors may be secured. In addition, as the connection line WL connecting the plurality of sub-pixels P to each other includes a composite material of a metal nanostructure and an elastic polymer, which may secure both stretchability and electrical characteristics, electrical signals may be stably transmitted to the plurality of sub-pixels P, and stress applied to the display apparatus 1 during stretching may also be relieved. As the conductive layers of the gate driving circuit GDC and the peripheral line PW, which are arranged in the non-display area NDA, include a liquid metal having a lower modulus than that of the connection line WL, stress at the outermost region of the display apparatus 1, which receives the highest stress, during stretching may be greatly relieved, thereby improving the stretchability of the display apparatus. In conclusion, the display apparatus according to one or more embodiments may concurrently (e.g., simultaneously) secure excellent stretchability and mechanical stability of the devices therein by arranging materials having different moduli for each area.

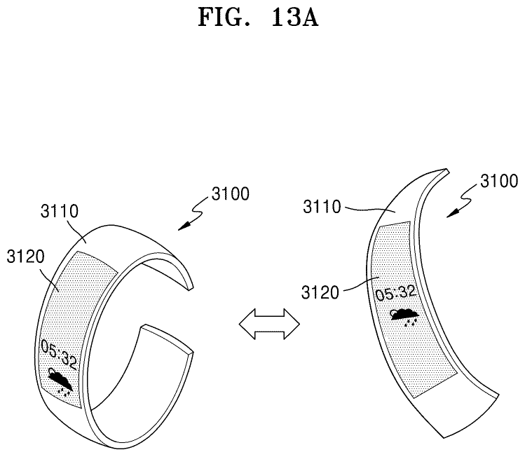

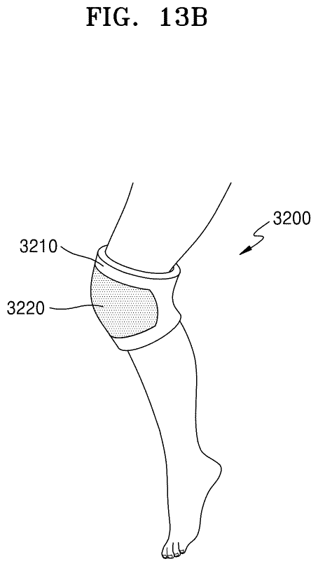

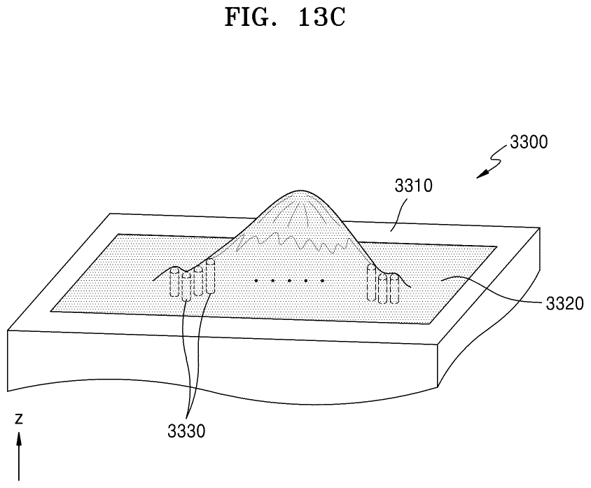

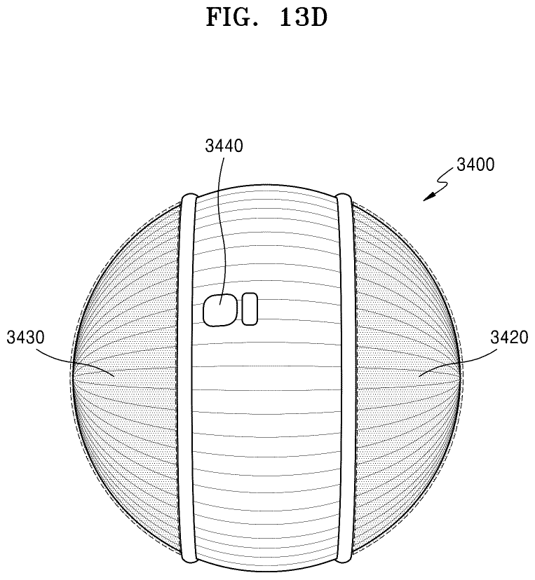

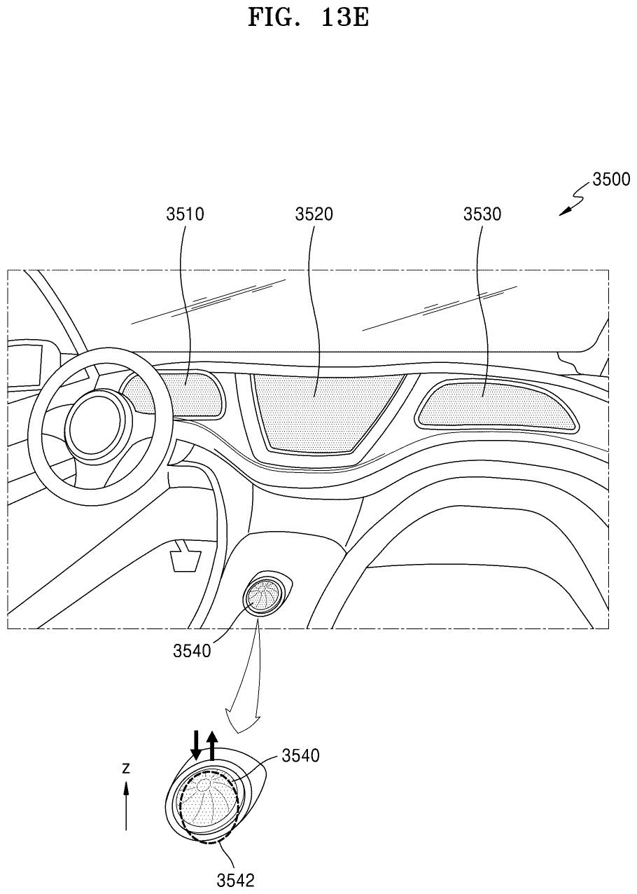

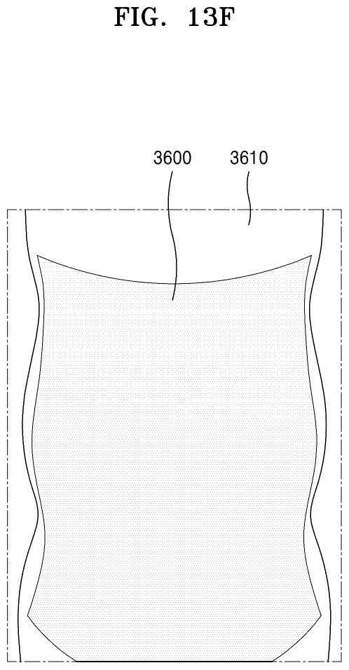

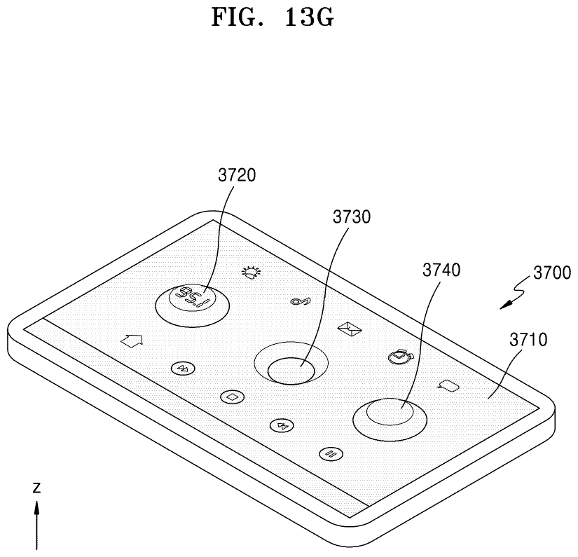

FIGS. 13A-13G are schematic perspective views respectively showing one or more embodiments of an electronic device including a display apparatus according to one or more embodiments.

Referring to FIG. 13A, a display apparatus according to one or more embodiments may be used as a wearable electronic device 3100 which may be worn on a part of a user's body. The wearable electronic device 3100 may include a body portion 3110 and a display portion 3120 provided in the body portion 3110. The display apparatus according to one or more embodiments may be used as the display portion 3120 of the wearable electronic device 3100. As shown in FIG. 13A, the wearable electronic device 3100 may be transformable. In one or more embodiments, the wearable electronic device 3100 may be used as a smart watch and/or a smartphone depending on the user's choice.

FIG. 13B shows a medical electronic device 3200. In one or more embodiments, the medical electronic device 3200 may include a body portion 3210 and a light-emitting portion 3220. The display apparatus according to one or more embodiments may be used as the light-emitting portion 3220 of the medical electronic device 3200. The light-emitting portion 3220 may emit light of a certain wavelength band (e.g., infrared light, visible light ray, and/or the like) to the body of a patient. In one or more embodiments, the body portion 3210 may include a stretchable fiber material and may have a structure that the light-emitting portion 3220 may be worn on the user's body.

FIG. 13C shows an educational electronic device 3300. In one or more embodiments, the educational electronic device 3300 may include a display portion 3320 provided in a frame 3310. The display portion 3320 may use the display apparatus according to one or more embodiments. The display portion 3320 may provide images, such as a sea with waves, a mountain covered with snow, and/or a volcano with flowing lava, and at this time, the display portion 3320 may extend in a height direction (e.g., a z direction) by reflecting the height of the waves, the mountain, and/or the volcano. In one or more embodiments, a portion of the display portion 3320 may three-dimensionally show the movement of lava by sequentially changing the height along a direction in which the lava flows. The educational electronic device 3300 may include a plurality of pins (or stroke portions) 3330 arranged on the rear surface of the display portion 3320 so that the display portion 3320 may be stretched in the height direction. While the pins 3330 move along a third direction (e.g., a z direction or a −z direction), an image displayed on the display portion 3320 may be implemented to have a three-dimensional height. FIG. 13 shows the educational electronic device 3300, but the use is not limited as long as the device provides certain image information.

As shown in FIGS. 13A-13C, an electronic device of which the shapes may be variable is described as the electronic device, but the present disclosure is not limited thereto. As to be described below, the display apparatus according to one or more embodiments may be used in an electronic device in which a portion capable of displaying images (e.g., a screen) is fixed.

FIG. 13D shows a robot 3400 as an electronic device according to one or more embodiments. The robot 3400 may recognize movement and/or objects by using a camera unit 3440 and may display certain images through display portions 3420 and 3430. In one or more embodiments, as described above, because the display apparatus according to one or more embodiments may be stretched in various directions, the display apparatus may be assembled into a body frame having a hemispherical shape, and accordingly, the robot 3400 may include the display portions 3420 and 3430 having hemispherical shapes.

FIG. 13E shows a vehicle display apparatus 3500 as an electronic device according to one or more embodiments. The vehicle display apparatus 3500 may include a cluster 3510, a center information display (CID) 3520, and/or a co-driver display 3530. Because the display apparatus according to one or more embodiments may be stretched in various directions, the display apparatus may be used in the cluster 3510, the CID 3520, and/or the co-driver display 3530 regardless of the shape of the internal frame of the vehicle.

FIG. 13E shows that the cluster 3510, the CID 3520, and the co-driver display 3530 are separated from each other, but the present disclosure is not limited thereto. In one or more embodiments, two or more selected from the cluster 3510, the CID 3520, and the co-driver display 3530 may be integrally connected to each other.

In one or more embodiments, the vehicle display apparatus 3500 may include a button 3540 that may display a certain image. Referring to the enlarged view of FIG. 13E, the button 3540 having a hemispherical shape may include an object 3542 that provides the feeling of using while moving in the z direction or the −z direction, and a display device disposed on the object 3542. In one or more embodiments, when the object 3542 has a three-dimensionally rounded surface, the display apparatus may also have a three-dimensionally rounded surface.

FIG. 13F shows that an electronic device according to one or more embodiments is an advertising and/or exhibiting electronic device 3600. In one or more embodiments, the advertising and/or exhibiting electronic device 3600 may be installed on a fixed structure 3610, such as a wall and/or a pillar. When the structure 3610 includes an uneven surface as shown in FIG. 13F, the advertising and/or exhibiting electronic device 3600 may be arranged along the uneven surface of the structure 3610. In one or more embodiments, the advertising and/or exhibiting electronic device 3600 may be installed on the structure 3610 by using a heat shrink film or the like.

FIG. 13G shows that an electronic device according to one or more embodiments is a controller 3700. The controller 3700 may include an image-type button. For example, the controller 3700 may include first to third button areas 3720, 3730, and 3740 in which a partial area of a display portion 3710 protrudes in a z direction or a −z direction (or is depressed in the z direction). In one or more embodiments, the first and third button areas 3720 and 3740 may protrude in the z direction, and the second button area 3730 may protrude in the −z direction (or may be depressed in the z direction).

According to one or more embodiments, a display apparatus which may prevent damage caused by concentration of stress and may be stretched in various directions is provided. However, these effects are shown as an example, and the scope of the present disclosure is not limited thereto.

It should be understood that embodiments described herein should be considered in a descriptive sense only and not for purposes of limitation. Descriptions of features and/or aspects within each embodiment should typically be considered as available for other similar features and/or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display apparatus including a display area and a non-display area outside the display area, the display apparatus comprising:
a plurality of pixels arranged in the display area, each of the plurality of pixels comprising a transistor and a light-emitting diode electrically connected to the transistor;
a connection line arranged in the display area, the connection line electrically connecting adjacent pixels from among the plurality of pixels to each other; and
a peripheral line arranged in the non-display area,
wherein a modulus of a conductive layer of the transistor is greater than a modulus of the connection line, and
wherein the modulus of the connection line is greater than a modulus of the peripheral line.

2. The display apparatus of claim 1, wherein the conductive layer of the transistor, the connection line, and the peripheral line comprise different materials.

3. The display apparatus of claim 1, wherein the modulus of the conductive layer of the transistor is greater than 100 GPa and less than 1000 GPa.

4. The display apparatus of claim 1, wherein the conductive layer of the transistor comprises a metal thin film.

5. The display apparatus of claim 1, wherein the modulus of the connection line is greater than 1 MPa and less than 100 MPa.

6. The display apparatus of claim 1, wherein the connection line comprises a metal nanostructure and an elastic polymer.

7. The display apparatus of claim 6, wherein the metal nanostructure comprises at least one of a silver (Ag) nanoparticle, an Ag nanoflake, or an Ag nanowire.

8. The display apparatus of claim 6, wherein the elastic polymer comprises at least one of polydimethylsiloxane (PDMS), polyurethane (PU), or Ecoflex.

9. The display apparatus of claim 6, wherein the connection line further comprises a carbon-based material, and
wherein the carbon-based material comprises a carbon nanotube (CNT), a carbon fiber, graphene, graphene oxide, or any combinations thereof.

10. The display apparatus of claim 1, wherein the modulus of the peripheral line is greater than 1 kPa and less than 100 kPa.

11. The display apparatus of claim 1, wherein the peripheral line comprises a liquid metal.

12. The display apparatus of claim 11, wherein the liquid metal comprises an eutectic gallium-indium alloy (EGaIn) or a gallium-indium-tin alloy (Galinstan).

13. The display apparatus of claim 1, wherein each of the conductive layer of the transistor, the connection line, and the peripheral line comprises a metal nanostructure and an elastic polymer.

14. The display apparatus of claim 13, wherein a concentration of the metal nanostructure in the conductive layer of the transistor is greater than a concentration of the metal nanostructure in the connection line, and
wherein the concentration of the metal nanostructure in the connection line is greater than a concentration of the metal nanostructure in the peripheral line.

15. The display apparatus of claim 13, wherein the metal nanostructure comprises at least one of an Ag nanoparticle, an Ag nanoflake, or an Ag nanowire, and
wherein the elastic polymer comprises at least one of polydimethylsiloxane (PDMS), polyurethane (PU), or Ecoflex.

16. The display apparatus of claim 1, wherein the connection line comprises a plurality of signal lines and a plurality of voltage lines, and
wherein the plurality of signal lines comprise at least one of a data line, an emission control line, a scan signal line, an initialization control line, or a bypass control line.

17. The display apparatus of claim 1, wherein the peripheral line comprises at least one of a driving voltage supply line, a common voltage supply line, a fan-out line, a driving circuit input line, or a driving circuit output line.

18. The display apparatus of claim 1, further comprising a gate driving circuit in the non-display area,
wherein a modulus of a conductive layer of the gate driving circuit is less than the modulus of the connection line.

19. The display apparatus of claim 18, wherein the conductive layer of the gate driving circuit comprises a liquid metal.

20. A display apparatus including a display area and a non-display area outside the display area, the display apparatus comprising:
a plurality of pixels arranged in the display area, each of the plurality of pixels comprising a transistor and a light-emitting diode electrically connected to the transistor;
a connection line arranged in the display area, the connection line electrically connecting adjacent pixels from among the plurality of pixels to each other; and
a peripheral line arranged in the non-display area,
wherein a conductive layer of the transistor comprises a metal thin film,
wherein the connection line comprises a metal nanostructure and an elastic polymer, and
wherein the peripheral line comprises a liquid metal.

21. The display apparatus of claim 20, wherein a modulus of the conductive layer of the transistor is greater than a modulus of the connection line, and
wherein the modulus of the connection line is greater than a modulus of the peripheral line.

22. The display apparatus of claim 21, wherein the modulus of the conductive layer of the transistor is from about 100 GPa to about 1000 GPa,
wherein the modulus of the connection line is from about 1 MPa to about 100 MPa, and
wherein the modulus of the peripheral line is from about 1 kPa to about 100 kPa.

23. The display apparatus of claim 20, wherein the metal nanostructure comprises at least one of a silver (Ag) nanoparticle, an Ag nanoflake, or an Ag nanowire, and
wherein the elastic polymer comprises at least one of polydimethylsiloxane (PDMS), polyurethane (PU), or Ecoflex.

24. The display apparatus of claim 20, wherein the liquid metal comprises an eutectic gallium-indium alloy (EGaIn) or a gallium-indium-tin alloy (Galinstan).
